(19) United States
(12) Patent Application Publication
(10) Pub. No.: US 2025/0002823 A1
(43) Pub. Date: Jan. 2, 2025

(54) Compositions For Removing Photoresist And Etch Residue From A Substrate With Copper Corrosion Inhibitor And Uses Thereof

(71) Applicant: Versum Materials US, LLC, Tempe, AZ (US)

(72) Inventors: YUANMEI CAO, Chandler, AZ (US); LILI WANG, Chandler, AZ (US); LAISHENG SUN, Gilbert, AZ (US); AIPING WU, Chandler, AZ (US)

(21) Appl. No.: 18/708,246

(22) PCT Filed: Nov. 30, 2022
(86) PCT No.: PCT/US22/80658

§ 371 Date: May 8, 2024

Related U.S. Application Data
(60) Provisional application No. 63/265,439, filed on Dec. 15, 2021.

(51) Int. Cl. C11D 7/32; B08B 3/08; C11D 7/06; C11D 7/26; C11D 7/50; G03F 7/42

(52) U.S. Cl. CPC C11D 7/3281; B08B 3/08; C11D 7/06; C11D 7/261; C11D 7/3209; C11D 7/3218; C11D 7/5009; C11D 7/5022; G03F 7/422

(57) ABSTRACT

The disclosed and claimed compositions relate to stripper solutions for the removal of photoresists and etch residue that include a triazine (e.g., benzoguanamine) corrosion inhibitor.

### BACKGROUND

### Field

The disclosed and claimed subject matter relates to compositions for removing photoresists and etch residue from substrates, and to methods for using such compositions. The disclosed and claimed compositions are stripper solutions for the removal of photoresists and etch residue that include a triazine corrosion inhibitor.

### Related Art

In semiconductor wafer manufacturing, wafer-level packaging (WLP) is the technology used to package an integrated circuit at the wafer-level including the addition of protective layers and electrical connections to the substrate before dicing. Usually, the interconnects are metal bumps produced from various processes including photolithography and metal deposition. The structures with deep holes are produced in photolithographic process and then the solder bump metals are filled into these holes. The bumps are then formed by removing the photoresist mask layer.

The photoresist layer is normally removed by a wet process using photoresist strippers. The requirements for effective photoresist strippers are not only the efficiency of photoresist removal, but also the good compatibility to the exposed substrates such as metal bumps and copper substrates. Photoresist stripper and etch residue removers for removal of photoresists and etch residue used in wafer level packaging are typically composed of different combinations of solvents, bases, corrosion inhibitors, optional co-solvents, and other additives. Conventional removers have DMSO (dimethyl sulfoxide) or NMP (N-methyl-2-pyrrolidone) as the solvent and quaternary ammonium hydroxides or inorganic bases, or combination thereof as bases. Bases are essential components for photoresist and etch residue removal. However, during the processes of removing photoresist layers, the copper substrates exposed to the photoresist strippers tend to be undesirably etched. As such, it is very critical for photoresist stripper and etch residue removers not to attack copper during cleaning process which can be achieved by introduction of effective and robust copper corrosion inhibitors.

Corrosion inhibitors are used to suppress the etch of exposed copper substrates. Many efforts have been used to find good copper inhibitors in photoresist strippers. The well-known copper corrosion inhibitors, such as benzotriazole, are effective in aqueous solutions. However, they do not work well in organic solvent-rich strippers containing strong bases. Metal salts such as copper salts are used as effective corrosion inhibitors however those salts have issues of solubility and stability in photoresist strippers. Sugar alcohols are also used as copper corrosion inhibitors however their efficiency in such organic solvent rich strippers could not meet the requirements of copper protection.

Triazine and its derivatives have only been selectively used as copper corrosion inhibitors. For example, JP2003213463A disclosed use of a triazine derivative as copper or copper alloy corrosion inhibitor in an alkaline or acidic aqueous cleaning solution to clean a semiconductor device having metal wiring. In JP2003213463A, the alkaline solution is an aqueous ammonia solution and/or an aqueous tetramethylammonium hydroxide solution.

Therefore, there is need to develop photoresist strippers with copper inhibitors to effectively protect copper substrates with high efficiency of photoresist removal.

### SUMMARY

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The disclosed and claimed subject matter is directed to photoresist stripper and etch residue remover solutions (collectively “remover solutions”) for removing or stripping (i) a positive or negative photoresist, (ii) photoresist etch residue after an etch process and/or (iii) etch residue from a substrate. The disclosed and claimed remover compositions are particularly excellent compatibility with copper even at high spin speed during application.

The disclosed subject matter relates to remover solutions that include, consist essentially of or consist of:
(i) one or more base component that includes one or more of an amine, a quaternary ammonium hydroxide, an inorganic base and combination thereof;
(ii) one or more organic solvents; and
(iii) one or more triazine derivative corrosion inhibitor of Formula (I):

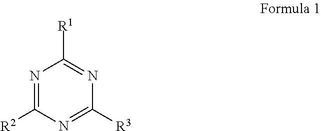

wherein each R¹, R² and R³ are each independently selected from a hydrogen atom, a hydroxyl group, a mercapto group, an amino group, a carboxyl group, a phenyl group, a substituted phenyl group, an alkoxy group or an alkyl group. In one aspect of this embodiment, two of R¹, R² and R³ are —NH₂.

In a further aspect, the solutions further optionally include, consist essentially of or consist of (iv) one or more secondary solvent(s). In a further aspect, the solutions further optionally include, consist essentially of or consist of (v) one or more non-triazine corrosion inhibitor. In a further aspect, the solutions further optionally include, consist essentially of or consist of (iv) one or more secondary solvent(s) and (v) one or more non-triazine corrosion inhibitor. In one aspect of these embodiments, the triazine corrosion inhibitor is a guanamine compound. In one aspect of these embodiments, the triazine corrosion inhibitor is benzoguanamine. In one aspect of these embodiments, the (iv) one or more secondary solvent(s) includes, consists essentially of or consists of water.

The disclosed and claimed subject matter is further directed to the use and synthesis of the disclosed and claimed chemical formulations. Among other things, the photoresist stripper and etch residue remover solutions can be used to remove polymeric resist materials present in a single layer or certain types of bilayer resists. For example, bilayer resists typically have either a first inorganic layer covered by a second polymeric layer or can have two polymeric layers.

In another embodiment, the disclosed and claimed subject matter is directed to methods of using a triazine derivative corrosion inhibitor to enhance the anti-corrosion properties of another non-triazine corrosion inhibitor (e.g., the (v) one or more non-triazine corrosion inhibitor). In one aspect of this embodiment, the triazine corrosion inhibitor is a guanamine compound. In one aspect of this embodiment, the triazine corrosion inhibitor is benzoguanamine.

Other features and advantages of the disclosed and claimed subject matter will be apparent from the following more detailed description, taken in conjunction with the example solutions which illustrate the principles of the disclosed and claimed subject matter.

The embodiments of the disclosed and claimed subject matter provide one or more of the following benefits: a photoresist stripper and etch residue remover with good cleaning-ability, high loading capacity, excellent compatibility with copper, silicon, silicon oxide and passivation material such as polyimide.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### Definitions

For the purposes of promoting an understanding of what is claimed, references will now be made to the embodiments illustrated and specific language will be used to describe the same. It will nevertheless be understood that no limitation of the scope of what is claimed is thereby intended, such alterations and further modifications and such further applications of the principles thereof as illustrated therein being contemplated as would normally occur to one skilled in the art to which the disclosure relates.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising.” “having.” “including.” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope thereof unless otherwise claimed. No language in the specification should be construed as indicating any non-claimed element as essential to the practice of the disclosed and claimed subject matter.

Preferred embodiments of disclosed and claimed subject matter are described herein, including the best mode known to the inventors for carrying out the disclosed and claimed subject matter. Variations of those preferred embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, this disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

For ease of reference, “microelectronic device” or “semiconductor substrates” correspond to semiconductor wafers, flat panel displays, phase change memory devices, solar panels and other products including solar substrates, photovoltaics, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly. The microelectronic device or semiconductor substrates may include low-k dielectric material, barrier materials, and metals, such as, Al, Cu, Cu alloy, SnAg alloy, W. Ti, TiN, one or more passivation layers, such as polyimide or polybenzoxazole, as well as Si, SiOₓ and other materials thereon.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon oxide, and carbon-doped oxide (CDO) glass. It is to be appreciated that the low-k dielectric materials may have varying densities and varying porosities.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, titanium tungsten, ruthenium, hafnium, and other refractory metals and their nitrides and silicides.

“Substantially free” is defined herein as less than approximately 1 wt. %, more preferably less than approximately 0.5 wt. %, and most preferably less than approximately 0.2 wt. %. “Substantially free” also includes approximately 0.0 wt. %. The term “free of” means 0.0 wt. %.

In some embodiments, when describing a composition that is substantially free of water, it is intended to mean that water may be added with the components as impurities; however, the amount of water added with the components should be less than approximately 0.1 wt %; however, water may be absorbed from the atmosphere during manufacturing and use. In other embodiments, substantially free of water may refer to compositions for which the water is not present above approximately 1 wt %. In other embodiments, substantially free of water may refer to compositions for which the water is not present above approximately 3 wt %. In other embodiments, water might be added as part of the raw material and the water level might be present above 2 wt % but less than 5%.

In some embodiments, the disclosed and claimed subject matter is free of amidoxime compounds. In some embodiments, the disclosed and claimed subject matter is free of metal-containing compounds.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all defined weight percent of the components unless otherwise indicated are based on the total weight of the composition. Further, all weight percent unless otherwise indicated are “neat” meaning that they do not include the aqueous solution in which they are present when added to the composition. Any reference to “at least one” could be substituted with “one or more.” “At least one” and/or “one or more” includes “at least two” or “two or more” and “at least three” and “three or more” and so on.

When referring to compositions (or solutions) herein in terms of weight %, it is understood that in no event shall the weight % of all components, including non-essential components, such as impurities, add to more than 100 weight %. In compositions “consisting essentially of” recited components, such components may add up to 100 weight % of the compositions or may add up to less than 100 weight %. Where the components add up to less than 100 weight %, such compositions may include some small amounts of a non-essential contaminants or impurities. For example, in one such embodiment, the compositions can contain 2% by weight or less of impurities. In another embodiment, the compositions can contain 1% by weight or less than of impurities. In a further embodiment, the compositions can contain 0.05% by weight or less than of impurities. In other such embodiments, the ingredients can form at least 90 wt %, more preferably at least 95 wt %, more preferably at least 99 wt %, more preferably at least 99.5 wt %, most preferably at least 99.8 wt %, and can include other ingredients that do not affect the performance of the wet etchant. Otherwise, if no significant non-essential impurity component is present, it is understood that the composition of all essential constituent components will essentially add up to 100 weight %.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As set forth above, the disclosed subject matter relates to remover solutions that include, consist essentially of or consist of:
(i) one or more base component that includes one or more of an amine, a quaternary ammonium hydroxide, an inorganic base and combination thereof;
(ii) one or more organic solvents; and
(iii) one or more triazine derivative corrosion inhibitor of Formula 1:

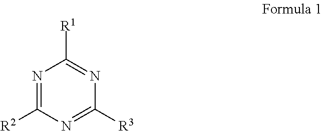

wherein each R¹, R² and R³ are each independently selected from a hydrogen atom, an oxygen-containing group, a hydroxyl group, a mercapto group, a nitrogen-containing group, an amine

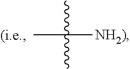

an amino group substituted with a C₁-C₁₀ alkyl group

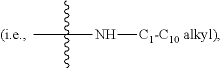

a carboxyl group, a phenyl group, a substituted phenyl group, an alkoxy group, a C₁ to C₂₀ linear alkyl group, a C₃ to C₂₀ branched alkyl group, a C₃ to C₁₀ cyclic alkyl group, a C₅ to C₁₂ aryl group, a C₂ to C₁₀ linear alkenyl group a C₃ to C₁₀ branched alkenyl group, a C₂ to C₁₀ linear alkynyl group, a C₃ to C₁₀ branched alkynyl group, a C₁ to C₂₀ linear alkyl group substituted with a halide and a C₁-C₂₀ alkyl substituted with

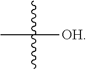 [SMILES: *O]

In one aspect of these embodiments, the triazine corrosion inhibitor is a guanamine compound (i.e., where at least two of R¹, R² and R³ are —NH₂). In one aspect of these embodiments, the triazine corrosion inhibitor is benzoguanamine.

In a further aspect, the solutions further optionally include, consist essentially of or consist of (iv) one or more secondary solvent(s). Thus, one aspect of this embodiment, the solutions include (i), (ii), (iii) and (iv). In one aspect of this embodiment, the solutions consist essentially of (i), (ii), (iii) and (iv). In a further aspect of this embodiment, the solutions consist of (i), (ii), (iii) and (iv). In one aspect of these embodiments, the triazine corrosion inhibitor is a guanamine compound. In one aspect of these embodiments, the triazine corrosion inhibitor is benzoguanamine.

In a further aspect, the solutions further optionally include, consist essentially of or consist of (v) one or more non-triazine corrosion inhibitor. Thus, one aspect of this embodiment, the solutions include (i), (ii), (iii) and (v). In one aspect of this embodiment, the solutions consist essentially of (i), (ii), (iii) and (v). In a further aspect of this embodiment, the solutions consist of (i), (ii), (iii) and (v). In one aspect of these embodiments, the triazine corrosion inhibitor is a guanamine compound. In one aspect of these embodiments, the triazine corrosion inhibitor is benzoguanamine.

In a further aspect, the solutions further optionally include, consist essentially of or consist of (iv) one or more secondary solvent(s) and (v) one or more non-triazine corrosion inhibitor. Thus, one aspect of this embodiment, the solutions include (i), (ii), (iii), (iv) and (v). In one aspect of this embodiment, the solutions consist essentially of (i), (ii), (iii), (iv) and (v). In a further aspect of this embodiment, the solutions consist of (i), (ii), (iii), (iv) and (v). In one aspect of these embodiments, the triazine corrosion inhibitor is a guanamine compound. In one aspect of these embodiments, the triazine corrosion inhibitor is benzoguanamine.

In another embodiment, the disclosed and claimed subject matter is directed to methods of using the disclosed and claimed photoresist stripper and etch residue remover solutions to remove photoresist and related polymeric materials from a substrate. In one aspect of this embodiment, a photoresist is removed from a substrate having a photoresist thereon by contacting the substrate with one or more of the photoresist stripper and etch residue remover solutions for a time sufficient to remove the desired amount of photoresist or etch residue, by removing the substrate from the stripping solution, rinsing the stripping solution from the substrate with DI water or a solvent, and drying the substrate.

In another embodiment, the disclosed and claimed subject matter is directed to methods of using a triazine derivative corrosion inhibitor to enhance the anti-corrosion properties of another non-triazine corrosion inhibitor (e.g., the (v) one or more non-triazine corrosion inhibitor). In one aspect of these embodiments, the triazine corrosion inhibitor is a guanamine compound. In one aspect of these embodiments, the triazine corrosion inhibitor is benzoguanamine.

### (i) Base Component

As noted above, the solutions of the disclosed and claimed subject matter include one or more base component that includes one or more of an amine, a quaternary ammonium hydroxide, an inorganic base and combination thereof.

### A. Amine

As noted above, the one or more base component can include one or more amine. Suitable amines include benzylamine, alkanolamines and alkylamines. Suitable alkanolamines include, but are not limited to, ethanolamine, N-methylethanolamine, N-ethylethanolamine, N-propylethanolamine, N-butylethanolamine, dimethylethanolamine, diethylethanolamine, diethanolamine, triethanolamine, N-methyldiethanolamine, N-ethyldiethanolamine, isopropanolamine, diisopropanolamine, triisopropanolamine, N-methylisopropanolamine, N-ethylisopropanolamine, N-propylisopropanolamine, 2-aminopropane-1-ol, N-methyl-2-aminopropane-1-ol, N-ethyl-2-aminopropane-1-ol, 1-aminopropane-3-ol, N-methyl-1-aminopropane-3-ol, N-ethyl-1-aminopropane-3-ol, 1-aminobutane-2-ol, N-methyl-1-aminobutane-2-ol, N-ethyl-1-aminobutane-2-ol, 2-aminobutane-1-ol, N-methyl-2-aminobutane-1-ol. N-ethyl-2-aminobutane-1-ol, 3-aminobutane-1-ol, N-methyl-3-aminobutane-1-ol, N-ethyl-3-aminobutane-1-ol, 1-aminobutane-4-ol, N-methyl-1-aminobutane-4-ol, N-ethyl-1-aminobutane-4-ol, 1-amino-2-methylpropane-2-ol, 2-amino-2-methylpropane-1-ol, 1-aminopentane-4-ol, 2-amino-4-methylpentane-1-ol, 2-aminohexane-1-ol, 3-aminoheptane-4-ol, 1-aminooctane-2-ol, 5-aminooctane-4-ol, 1-aminopropane-2,3-diol, 2-aminopropane-1,3-diol, tris(oxymethyl)aminomethane, 1,2-diaminopropane-3-ol, 1,3-diaminopropane-2-ol, 2-(2-aminoethoxy) ethanol, 4-(2-hydroxyethyl) morpholine, 1-(2-hydroxyethyl) piperidine, and 1-(2-hydroxyethyl) piperazine. Suitable alkylamines include but not limit to diethylenetriamine, triethylenetetramine, 1,5-diamino-2-methylpentane, 1,3-diaminopentane, piperazine, 1-(2-aminoethyl) piperazine, 1,2-diaminocyclohexane, 1,3-diaminopropane, 1-(2-aminoethyl) piperidine, and tetraethylenepentamine, pentamethyldiethylenetriamine. Preferred alkanolamines include N-methylethanolamine, N-ethylethanolamine, ethanolamine, N-methyldiethanolamine, monoisopropanolamine and aminoethoxyethanol. Preferred alkylamines include diethylenetriamine, pentamethyldiethylenetriamine and triethylenetetramine.

In one embodiment, the solutions include about 0.5 wt % to about 20 wt % of one or more alkanolamine. In one embodiment, the solutions include about 2.5 wt % to about 15 wt % of one or more alkanolamine. In one embodiment, the solutions include about 5 wt % to about 15 wt % of one or more alkanolamine. In one embodiment, the solutions include about 5 wt % to about 10 wt % of one or more alkanolamine. In one embodiment, the solutions include about 10 wt % to about 20 wt % of one or more alkanolamine.

In one embodiment, the solutions include about 2.6 wt % neat DMDPAH (dimethyldipropylammonium hydroxide) and about 1 wt % to about 12 wt % of monoethanolamine (MEA). In a further aspect of this embodiment, the solutions include about 2 wt % to about 10 wt % of MEA. In another aspect of this embodiment, the solutions include about 3 wt % to about 9 wt % of MEA. In another aspect of this embodiment, the solutions include about 4 wt % to about 8 wt % of MEA. In another aspect of this embodiment, the solutions include about 5 wt % to about 7 wt % of MEA. In another aspect of this embodiment, the solutions include about 2.5 wt % of MEA. In another aspect of this embodiment, the solutions include about 3 wt % of MEA. In another aspect of this embodiment, the solutions include about 3.5 wt % of MEA. In another aspect of this embodiment, the solutions include about 4 wt % of MEA. In another aspect of this embodiment, the solutions include about 4.5 wt % of MEA. In another aspect of this embodiment, the solutions include about 5 wt % of MEA. In another aspect of this embodiment, the solutions include about 6 wt % of MEA.

In one embodiment, the solutions include about 2.6 wt % neat DMDPAH and about 1 wt % to about 12 wt % of N-methyldiethanolamine (NMDEA). In a further aspect of this embodiment, the solutions include about 2 wt % to about 10 wt % of NMDEA. In another aspect of this embodiment, the solutions include about 3 wt % to about 9 wt % of NMDEA. In another aspect of this embodiment, the solutions include about 4 wt % to about 8 wt % of NMDEA. In another aspect of this embodiment, the solutions include about 5 wt % to about 7 wt % of NMDEA. In another aspect of this embodiment, the solutions include about 2 wt % of NMDEA. In another aspect of this embodiment, the solutions include about 2.5 wt % of NMDEA. In another aspect of this embodiment, the solutions include about 3 wt % of NMDEA. In another aspect of this embodiment, the solutions include about 3.5 wt % of NMDEA. In another aspect of this embodiment, the solutions include about 4 wt % of NMDEA. In another aspect of this embodiment, the solutions include about 4.5 wt % of NMDEA. In another aspect of this embodiment, the solutions include about 5 wt % of NMDEA. In another aspect of this embodiment, the solutions include about 6 wt % of NMDEA.

### B. Quaternary Ammonium Hydroxide

As noted above, the one or more base component can include one or more quaternary ammonium hydroxide. Suitable quaternary ammonium hydroxides include, but are not limited to, tetramethylammonium hydroxide (TMAH), tetraethylammonium hydroxide (TEAH), tetrapropylammonium hydroxide (TPAH), tetrabutylammonium hydroxide (TBAH), ethyltrimethylammonium hydroxide (ETMAH), benzyltrimethylammonium hydroxide (BTMAH), choline hydroxide and dimethyldipropylammonium hydroxide (DMDPAH). In some embodiments, TEAH is preferentially included. In such embodiments, the TEAH is used as an aqueous solution, for example a 35 wt % aqueous solution. In other embodiments, DMDPAH is preferentially included. In such embodiments, the DMDPAH is used as 20 wt % solution in propylene glycol. In some embodiments, the solutions are free from TMAH.

The quaternary ammonium hydroxide may be present in any neat amounts ranging from about 0.5 wt % to about 20 wt %, 1 wt % to about 15 wt %, or from about 1 wt % to about 14 wt %, or from about 1 wt % to about 13 wt % or from about 1 wt % to about 12 wt %, or from about 1 wt % to about 11 wt %, or from about 1 wt % to about 10 wt %, or from about 1 wt % to about 9 wt %, or from about 1 wt % to about 8 wt %, or from about 1 wt % to about 7 wt %, or from about 1 wt % to about 6 wt %, or from about 1 wt % to about 5 wt %, or from about 1 wt % to about 4 wt %, or from about 1 wt % to about 3 wt %, or from about 1 wt % to about 2 wt %, or from about 0.1 wt % to about 0.9 wt %, or from about 0.4 wt % to about 0.5 wt %, or from about 0.1 wt % to about 0.2 wt % by weight based on the total weight of the composition. More preferably, the quaternary ammonium hydroxide is present, but in an amount not greater than 20 wt % by weight. In certain preferred compositions, the quaternary ammonium hydroxide is present at about 8 wt % to 15 wt % by weight. In certain preferred compositions, the quaternary ammonium hydroxide is present at about 8 wt % to 13 wt % by weight. In certain preferred compositions, the quaternary ammonium hydroxide is present at about 10 wt % to 15 wt % by weight.

In one embodiment, the solutions include about 7 wt % to 15 wt % by weight of neat TEAH. In a further aspect of this embodiment, the solutions include about 8 wt % to about 14 wt % of neat TEAH. In another aspect of this embodiment, the solutions include about 9 wt % to about 13 wt % of neat TEAH. In another aspect of this embodiment, the solutions include about 10 wt % to about 11 wt % of neat TEAH. In another aspect of this embodiment, the solutions include about 12 wt % of neat TEAH. In another aspect of this embodiment, the solutions include about 12.2 wt % of neat TEAH. In another aspect of this embodiment, the solutions include about 12.4 wt % of neat TEAH. In another aspect of this embodiment, the solutions include about 12.6 wt % of neat TEAH. In another aspect of this embodiment, the solutions include about 12.8 wt % of neat TEAH. In another aspect of this embodiment, the solutions include about 13 wt % of neat TEAH. In another aspect of this embodiment, the solutions include about 13.2 wt % of neat TEAH. In another aspect of this embodiment, the solutions include about 13.4 wt % of neat TEAH. In another aspect of this embodiment, the solutions include about 13.6 wt % of neat TEAH.

In one embodiment, the solutions include about 1 wt % to 5 wt % by weight of neat DMDPAH. In a further aspect of this embodiment, the solutions include about 1 wt % to about 4.5 wt % of neat DMDPAH. In another aspect of this embodiment, the solutions include about 1.5 wt % to about 4 wt % of neat DMDPAH. In another aspect of this embodiment, the solutions include about 2 wt % to about 3.5 wt % of neat DMDPAH. In another aspect of this embodiment, the solutions include about 2 wt % to about 3 wt % of neat DMDPAH. In another aspect of this embodiment, the solutions include about 2.1 wt % of neat DMDPAH. In another aspect of this embodiment, the solutions include about 2.2 wt % of neat DMDPAH. In another aspect of this embodiment, the solutions include about 2.3 wt % of neat DMDPAH. In another aspect of this embodiment, the solutions include about 2.4 wt % of neat DMDPAH. In another aspect of this embodiment, the solutions include about 2.6 wt % of neat DMDPAH. In another aspect of this embodiment, the solutions include about 2.8 wt % of neat DMDPAH. In another aspect of this embodiment, the solutions include about 3 wt % of neat DMDPAH.

In one embodiment, the solutions include about 8 wt % to 15 wt % by weight of neat choline hydroxide. In a further aspect of this embodiment, the solutions include about 9 wt % to about 14 wt % of neat choline hydroxide. In a further aspect of this embodiment, the solutions include about 10 wt % to about 13 wt % of neat choline hydroxide. In a further aspect of this embodiment, the solutions include about 11 wt % to about 12 wt % of neat choline hydroxide. In another aspect of this embodiment, the solutions include about 12 wt % to about 13 wt % of neat choline hydroxide. In another aspect of this embodiment, the solutions include about 11.25 wt % of neat choline hydroxide. In another aspect of this embodiment, the solutions include about 10.2 wt % of neat choline hydroxide. In another aspect of this embodiment, the solutions include about 10.4 wt % of neat choline hydroxide. In another aspect of this embodiment, the solutions include about 10.6 wt % of neat choline hydroxide. In another aspect of this embodiment, the solutions include about 10.8 wt % of neat choline hydroxide. In another aspect of this embodiment, the solutions include about 11 wt % of neat choline hydroxide. In another aspect of this embodiment, the solutions include about 11.2 wt % of neat choline hydroxide. In another aspect of this embodiment, the solutions include about 11.4 wt % of neat choline hydroxide. In another aspect of this embodiment, the solutions include about 11.6 wt % of neat choline hydroxide. In another aspect of this embodiment, the solutions include about 11.8 wt % of neat choline hydroxide. In another aspect of this embodiment, the solutions include about 12 wt % of neat choline hydroxide.

### C. Inorganic Base

As noted above, the one or more base component that includes one or more inorganic base. Preferably, the one or more inorganic base includes at least one alkali metal hydroxide or a mixture of different alkali metal hydroxides. Suitable inorganic bases include, but are not limited to sodium hydroxide, potassium hydroxide, lithium hydroxide, rubidium hydroxide and cesium hydroxide. In some embodiments, potassium hydroxide is preferentially included. In such embodiments, the potassium hydroxide is used as an aqueous solution, for example a 48 wt % aqueous solution. In other such embodiments, the potassium hydroxide is used as a solid, for example an 85 wt % or 90 wt % flake.

The metal hydroxide may be present in any neat amounts ranging from about 0.1% to about 5%, or from about 0.1 wt % to about 4 wt %, or from about 0.9 wt % to about 4 wt % or from about 0.1 wt % to about 0.8 wt %, or from about 0.4 wt % to about 0.5 wt %, or from about 0.1 wt % to about 0.2 wt % by weight based on the total weight of the composition. More preferably, the metal hydroxide is present, but in an amount not greater than 3.5 wt % by weight. In certain preferred compositions, the metal hydroxide is present at about 1.0 wt % to 2.5 wt % by weight. In certain preferred compositions, the metal hydroxide is present at about 1.5 wt % to 2.25 wt % by weight.

In one embodiment, the solutions include about 0.5 wt % to about 3.5 wt % of neat KOH. In one embodiment, the solutions include about 1.0 wt % to about 2.5 wt % of neat KOH. In a further aspect of this embodiment, the solutions include about 1.75 wt % to about 2.25 wt % of neat KOH. In another aspect of this embodiment, the solutions include about 1.75 wt % to about 2.1 wt % of neat KOH. In another aspect of this embodiment, the solutions include about 1.75 wt % to about 2.05 wt % of neat KOH. In another aspect of this embodiment, the solutions include about 1.75 wt % to about 2.0 wt % of neat KOH. In another aspect of this embodiment, the solutions include about 1 wt % of neat KOH. In another aspect of this embodiment, the solutions include about 1.25 wt % of neat KOH. In another aspect of this embodiment, the solutions include about 1.5 wt % of neat KOH. In another aspect of this embodiment, the solutions include about 1.75 wt % of neat KOH. In another aspect of this embodiment, the solutions include about 1.8 wt % of neat KOH. In another aspect of this embodiment, the solutions include about 1.9 wt % of neat KOH. In another aspect of this embodiment, the solutions include about 2.0 wt % of neat KOH. In another aspect of this embodiment, the solutions include about 2.05 wt % of neat KOH. In another aspect of this embodiment, the solutions include about 2.1 wt % of neat KOH. In another aspect of this embodiment, the solutions include about 2.15 wt % of neat KOH. In another aspect of this embodiment, the solutions include about 2.2 wt % of neat KOH. In another aspect of this embodiment, the solutions include about 2.25 wt % of neat KOH. In another aspect of this embodiment, the solutions include about 2.3 wt % of neat KOH.

In one embodiment, the solutions include about 1.0 wt % to about 2.5 wt % of neat NaOH. In a further aspect of this embodiment, the solutions include about 1.75 wt % to about 2.25 wt % of neat NaOH. In another aspect of this embodiment, the solutions include about 1.75 wt % to about 2.1 wt % of neat NaOH. In another aspect of this embodiment, the solutions include about 1.75 wt % to about 2.05 wt % of NaOH. In another aspect of this embodiment, the solutions include about 1.75 wt % to about 2.0 wt % of neat NaOH. In another aspect of this embodiment, the solutions include about 1 wt % of neat NaOH. In another aspect of this embodiment, the solutions include about 1.25 wt % of neat NaOH. In another aspect of this embodiment, the solutions include about 1.5 wt % of neat NaOH. In another aspect of this embodiment, the solutions include about 1.75 wt % of neat NaOH. In another aspect of this embodiment, the solutions include about 1.8 wt % of neat NaOH. In another aspect of this embodiment, the solutions include about 1.9 wt % of neat NaOH. In another aspect of this embodiment, the solutions include about 2.0 wt % of neat NaOH. In another aspect of this embodiment, the solutions include about 2.05 wt % of neat NaOH. In another aspect of this embodiment, the solutions include about 2.1 wt % of neat NaOH. In another aspect of this embodiment, the solutions include about 2.15 wt % of neat NaOH. In another aspect of this embodiment, the solutions include about 2.2 wt % of neat NaOH. In another aspect of this embodiment, the solutions include about 2.25 wt % of neat NaOH. In another aspect of this embodiment, the solutions include about 2.3 wt % of neat NaOH.

In one embodiment, the solutions include about 1.0 wt % to about 7.5 wt % of neat CsOH. In a further aspect of this embodiment, the solutions include about 1.75 wt % to about 7.25 wt % of neat CsOH. In another aspect of this embodiment, the solutions include about 1.75 wt % to about 7 wt % of neat CsOH. In another aspect of this embodiment, the solutions include about 1.75 wt % to about 6.0 wt % of CsOH. In another aspect of this embodiment, the solutions include about 1.75 wt % to about 5.0 wt % of neat CsOH. In another aspect of this embodiment, the solutions include about 1 wt % of neat CsOH. In another aspect of this embodiment, the solutions include about 1.5 wt % of neat CsOH. In another aspect of this embodiment, the solutions include about 2.0 wt % of neat CsOH. In another aspect of this embodiment, the solutions include about 2.5 wt % of neat CsOH. In another aspect of this embodiment, the solutions include about 3.0 wt % of neat CsOH. In another aspect of this embodiment, the solutions include about 3.5 wt % of neat CsOH. In another aspect of this embodiment, the solutions include about 4.0 wt % of neat CsOH. In another aspect of this embodiment, the solutions include about 4.5 wt % of neat CsOH. In another aspect of this embodiment, the solutions include about 5.0 wt % of neat CsOH. In another aspect of this embodiment, the solutions include about 5.5 wt % of neat CsOH. In another aspect of this embodiment, the solutions include about 6.0 wt % of neat CsOH. In another aspect of this embodiment, the solutions include about 6.5 wt % of neat CsOH. In another aspect of this embodiment, the solutions include about 7.0 wt % of neat CsOH. In another aspect of this embodiment, the solutions include about 7.5 wt % of neat CsOH.

### (ii) Organic Solvents

The solutions of the disclosed and claimed subject matter include one or more organic solvents and optionally a secondary solvent.

In one embodiment, the solutions include about 50 wt % to about 98 wt % of the one or more organic solvents. In a further aspect of this embodiment, the solutions include about 94 wt % to about 97 wt % of the one or more organic solvents. In a further aspect of this embodiment, the solutions include about 90 wt % to about 94 wt % of the one or more organic solvents. In a further aspect of this embodiment, the solutions include about 83 wt % to about 90 wt % of the one or more organic solvents. In a further aspect of this embodiment, the solutions include about 75 wt % to about 83 wt % of the one or more organic solvents. In a further aspect of this embodiment, the solutions include about 65 wt % to about 75 wt % of the one or more organic solvents. In a further aspect of this embodiment, the solutions include about 60 wt % to about 65 wt % of the one or more organic solvents. In a further aspect of this embodiment, the solutions include about 50 wt % to about 60 wt % of the one or more organic solvents. In a further aspect of this embodiment, the solutions include about 40 wt % to about 98 wt % of the one or more organic solvents. In a further aspect of this embodiment, the solutions include about 40 wt % to about 50 wt % of the one or more organic solvents. In a further aspect of this embodiment, the amount (wt %) of the one or more organic solvent exceeds the amount (wt %) of any secondary solvent(s) present.

In some embodiments, the solvent is selected from an ether alcohol. One type of ether alcohol solvent may be a glycol ether. Suitable glycol ether solvents include, but are not limited to, diethylene glycol butyl ether (DB), diethylene glycol methyl ether, diethylene glycol ethyl ether, diethylene glycol propyl ether, propylene glycol methyl ether, dipropylene glycol methyl ether, propylene glycol propyl ether, dipropylene glycol propyl ether, propylene glycol phenyl ether, propylene glycol n-butyl ether, dipropylene glycol n-butyl ether, ethylene glycol propyl ether, ethylene glycol butyl ether, ethylene glycol phenyl ether, tripropylene glycol methyl ether, dipropylene glycol dimethyl ether, diethylene glycol methyl ethyl ether, diethylene glycol dimethyl ether, diethylene glycol diethyl ether, triethylene glycol monomethyl ether (TEGME), triethylene glycol monoethyl ether, triethylene glycol monopropyl ether and triethylene glycol monobutyl ether. Other suitable types of ether alcohol solvents that are not glycol ethers (i.e., other alcohols having an ether group). Examples are 3-methoxy-3-methyl-1-butanol (MMB), furfuryl alcohol, tetrahydrofurfuryl alcohol. Other suitable solvents are DMSO, NMP and sulfolane.

In one embodiment, the solvent includes diethylene glycol monoethyl ether (DE solvent). In a further aspect of this embodiment, the solvent is about 40 wt % to about 80 wt % of diethylene glycol monoethyl ether (DE solvent). In another embodiment, the solvent includes DMSO. In a further aspect of this embodiment, the solvent is about 50 wt % to about 90 wt % of DMSO.

In some embodiments, the solutions are free or essentially free of an amide-containing solvent. By essentially free it is meant an amount less than 1 percent, alternately less than 0.1 weight percent, alternately less than 0.01 weight percent, or less than 0.001 weight percent, or free of, where free of is non-detectable or 0.

In other embodiments, the solutions may be free or essentially free of a sulfur containing solvent. In a further aspect of this embodiment, the compositions are free or essentially free of N-methyl-2-pyrrolidone (NMP). In a further aspect of this embodiment, the compositions are free or essentially free of DMSO. By essentially free it is meant an amount less than 1 percent, alternately less than 0.1 weight percent, alternately less than 0.01 weight percent, or less than 0.001 weight percent, or free of, where free of is non-detectable or 0.

(iii) Triazine Derivative Corrosion Inhibitors

As noted above, the solutions of the disclosed and claimed subject matter include one or more triazine derivative corrosion inhibitor of Formula (I):

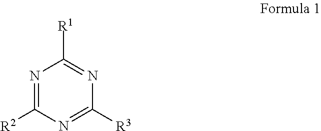

wherein each R¹, R² and R³ are each independently selected from a hydrogen atom, an oxygen-containing group, a hydroxyl group, a mercapto group, a nitrogen-containing group, an amine

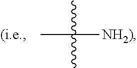

an amino group substituted with a C₁-C₁₀ alkyl group

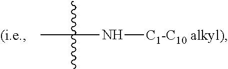

a carboxyl group, a phenyl group, a substituted phenyl group, an alkoxy group, a C₁ to C₂₀ linear alkyl group, a C₃ to C₂₀ branched alkyl group, a C₃ to C₁₀ cyclic alkyl group, a C₅ to C₁₂ aryl group, a C₂ to C₁₀ linear alkenyl group a C₃ to C₁₀ branched alkenyl group, a C₂ to C₁₀ linear alkynyl group, a C₃ to C₁₀ branched alkynyl group, a C₁ to C₂₀ linear alkyl group substituted with a halide and a C₁-C₂₀ alkyl substituted with

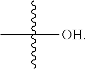 [SMILES: *O]

In one embodiment, at least one of R¹, R² and R³ is phenyl group.

In one embodiment, at least one of R¹, R² and R³ is amine.

In one embodiment, at least two of R¹, R² and R³ are an amine.

In one embodiment, one of R¹, R² and R³ is phenyl group and the remaining two of R¹, R² and R³ are an amine.

In one embodiment, at least one of R¹, R² and R³ is a substituted phenyl group. In one aspect of this embodiment, the phenyl group is substituted with one or more of a hydroxyl group, a mercapto group, an amino group, an imino group, a carboxyl group, a phenyl group, an alkyl group and an alkoxy group having 1 to 10 carbon atoms, linear or branched group.

In one embodiment, at least one of R¹, R² and R³ is an alkoxy group having 1 to 10 carbon atoms that is one or more of a methoxy group, an ethoxy group, a propoxy group and a butoxy group.

In one embodiment, at least one of R¹, R² and R³ is an alkyl group having 1 to 20 carbons that is one or more of a methyl group, an ethyl group, a propyl group, a butyl group, a nonyl group, and a lauryl group. In a further aspect of this embodiment, the alkyl group having 1 to 20 carbons is substituted with one or more of a hydroxyl group, a mercapto group, an amino group, an imino group, a carboxyl group, a phenyl group and an alkoxy group having 1 to 10 carbon atoms.

In one embodiment, the one or more triazine derivative corrosion inhibitor is one or more of 1,2,3-triazine, 1,2,4-triazine, and 1,3,5-triazine and substituted triazines. 1,3,5-triazine and substituted 1,3,5-triazine are preferred copper inhibitors in the disclosed and claimed subject matter, and specific examples include but not limited to 2,4-diamino-6-methyl-1,3,5-triazine and 2,4-diamino-1,3,5-triazine, 2-amino-1,3,5-triazine, 2,4-diamino-6-isobutyl-1,3,5-triazine, 2,4-diamino-6-xylyl-1,3,5-triazine, 2,4-diamino-6-hydroxy-1,3,5-triazine, 2,4-diamino-6-phenyl-1,3,5-triazine, 2-amino-4-methoxy-6-methyl-1,3,5-triazine and 2,4,6-triamino-1,3,5-triazine. Other preferred triazines include 2-amino-1,2,4-triazine and 3-amino-5,6-dimethyl-1,2,4-triazine.

In one preferred embodiment, the one or more triazine derivative corrosion inhibitor is one or more guanamine compounds (i.e., compounds of Formula 1 where two of R¹, R² and R³ each are —NH₂) as shown in Formula 2 (where R² and R³ are —NH₂):

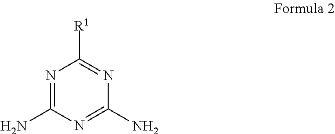

In one preferred embodiment, the one or more triazine derivative corrosion inhibitor is one or more guanamine compounds (i.e., compounds of Formula 1 where two of R¹, R² and R³ each are —NH₂) as shown in Formula 3 (where R² and R³ are —NH₂) and R¹ is selected from hydrogen, an —OH group, a carboxyl group, a phenyl group, a substituted phenyl group, an amine, a C₁-C₆ linear alkyl group and a C₃-C₆ branched chain alky group:

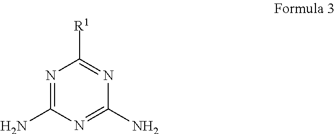

In one preferred embodiment, the one or more triazine derivative corrosion inhibitor is one or more guanamine compound that is or includes 2,4-diamino-6-phenyl-1,3,5-triazine (“benzoguanamine”) where two of R¹, R² and R³ are —NH₂ and the other of R¹, R² and R³ is a phenyl group:

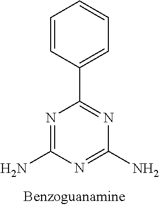 [SMILES: Nc1nc(N)nc(-c2ccccc2)n1]

In another embodiment, the one or more triazine derivative corrosion inhibitor is 1,3,5-triazine-2,4,6-triamine (melamine) where each of R¹, R² and R³ is-NH₂:

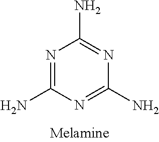

In one embodiment, the one or more triazine derivative corrosion inhibitor is present in the solutions at levels ranging from about 0.005 wt % to about 10 wt %. In one embodiment, the solution may contain about 0.1 weight percent to about 10 weight percent or about 0.5 weight percent to about 10 weight percent or about 0.5 weight percent to about 5 weight percent o or about 0.5 weight percent to about 3 weight percent or 0.1 weight percent to about 4 weight percent or about 0.25 weight percent to about 2 weight percent or about 0.01 weight percent to about 4 weight percent or about 0.05 weight percent to about 4 weight percent or about 0.1 weight percent to about 4 weight percent. In one embodiment, the solution may contain about 0.25 weight percent to about 1 weight percent. The one or more corrosion inhibitors may be present in any amount defined by the endpoints selected from the following weight percents: 0.005, 0.02, 0.08, 0.1, 0.2, 0.25, 0.3, 0.4, 0.5, 0.7, 0.9, 1, 2, 3, 4, 5, 6, 7, 8, 9 and 10.

### (iv) Secondary Solvents (Optional)

Some embodiments may contain a secondary solvent in addition to the DMSO or ether alcohol solvents described above. Alternatively, in some embodiments, the stripper solutions may be free or substantially free of a secondary solvent.

In some embodiments, the (iv) secondary solvent includes one of water, alcohols, polyhydroxyl compounds. In one aspect of this embodiment, the (iv) secondary solvent is water. In another aspect of this embodiment, the (iv) secondary solvent is one or more of ethylene glycol, propylene glycol and glycerol. In one embodiment, the (iv) secondary solvent is about 13 wt % to about 40 wt % of water. In another embodiment, the (iv) secondary solvent is about 5 wt % to about 15 wt % of propylene glycol.

In one aspect, the (iv) secondary solvent includes added water (i.e., water added as a solvent as opposed to de minimus amounts of water present as impurities in other ingredients). In one embodiment, the (iv) secondary solvent is about 0.1 wt % to about 45 wt % of water. In one embodiment, the (iv) secondary solvent is about 0.2 wt % to about 45 wt % of water. In one embodiment, the (iv) secondary solvent is about 5 wt % to about 35 wt % of water. In one embodiment, the (iv) secondary solvent is about 0.5 wt % to about 25 wt % of water. In one embodiment, the (iv) secondary solvent is about 0.2 wt % of water. In one embodiment, the (iv) secondary solvent is about 0.5 wt % of water. In one embodiment, the (iv) secondary solvent is about 1 wt % of water. In one embodiment, (iv) the secondary solvent is about 2.5 wt % of water. In one embodiment, the (iv) secondary solvent is about 5 wt % of water. In one embodiment, the (iv) secondary solvent is about 7.5 wt % of water. In one embodiment, the (iv) secondary solvent is about 10 wt % of water. In one embodiment, the secondary solvent is about 15 wt % of water. In one embodiment, the (iv) secondary solvent is about 20 wt % of water. In one embodiment, the (iv) secondary solvent is about 24 wt % of water. In one embodiment, the (iv) secondary solvent is about 25 wt % of water. In one embodiment, the (iv) secondary solvent is about 30 wt % of water. In one embodiment, the (iv) secondary solvent is about 35 wt % of water. In one embodiment, the (iv) secondary solvent is about 40 wt % of water. In one embodiment, the (iv) secondary solvent is about 45 wt % of water.

In one embodiment, the (iv) secondary solvent is free of water. In one embodiment, the (iv) secondary solvent is substantially free of water. In one embodiment, the (iv) secondary solvent includes less than about 0.05 wt % of water. In one embodiment, the (iv) secondary solvent includes less than 0.1 wt % of water.

Secondary organic solvent alcohols or polyhydroxy compound may be linear or branched chain aliphatic or aromatic alcohols. Examples of the secondary alcohols that the composition may comprise include methanol, ethanol, propanol, isopropyl alcohol, butanol, tert-butyl alcohol, tert-amyl alcohol, 3-methyl-3-pentanol, 1-octanol, 1-decanol, 1-undecanol, 1-dodecanol, 1-tridecanol, 1-tetradecanol, 1-pentadecanol, 1-hexadecanol, 9-hexadecen-1-ol, 1-heptadecanol, 1-octadecanol, 1-nonadecanol, 1-eicosanol, 1-heneicosanol, 1-docosanol, 13-docosen-1-ol, 1-tetracosanol, 1-hexacosanol, 1-heptacosanol, 1-octacosanol, 1-triacontanol, 1-dotriacontanol, 1-tetratriacontanol, cetearyl alcohol, ethylene glycol, propylene glycol and glycerol.

When used, the (iv) secondary organic solvent may include from about 0.02% to about 50%, or from about 0.08% to about 38%, or from about 0.1% to about 35%, or from about 0.2% to about 33%, or from about 0.3% to about 20%, or from about 5% to about 15% of the composition. In alternative embodiments the secondary solvent may be present in any amount defined by the endpoints selected from the following weight percents: 0.02, 0.08, 0.1, 0.2, 0.3, 0.4, 0.5, 0.7, 0.9, 1, 3, 5, 8, 10, 12, 15, 17, 20, 23, 25, 38, 30, 32, 35, 37, 40, 43, 45, 47 and 50.

In a further aspect of the above embodiments, the amount (wt %) of the one or more organic solvent exceeds the amount (wt %) of the secondary solvent(s) present.

### (v) Optional Non-Triazine Corrosion Inhibitor

In a further aspect, the solutions further optionally include, consist essentially of or consist of (v) one or more non-triazine corrosion inhibitor. Suitable non-triazine corrosion inhibitors include, but are not limited to, organic corrosion inhibitors, including, aromatic hydroxyl compounds, and aromatic polyhydroxyl compounds such as catechol and resorcinol; allylcatechols, such as methylcatechol, ethylcatechol and t-butylcatechol, phenols and pyrogallol; aromatic triazoles such as benzotriazole (BZT); alkylbenzotriazoles and methylbenzotriazole, aminobenzotriazoles, such as, 1-aminobenzotriazole; thiazoles, such as, 2-aminobenzothiazole (ABT); sugar alcohols such as glycerol, xylitol and sorbitol, 8-HQ (8-hydroxy quinoline), histidine and copper salts such as copper nitrates.

In one embodiment, the (v) one or more optional non-triazine corrosion inhibitor is present in the solutions at levels ranging from about 0.005 wt % to about 10 wt %. In one embodiment, the solution may contain about 0.005 weight percent to about 5 weight percent or about 0.025 weight percent to about 4 weight percent or about 0.05 weight percent to about 4 weight percent or about 0.1 weight percent to about 4 weight percent or 0.1 weight percent to about 10 weight percent or about 0.25 weight percent to about 8 weight percent or about 0.5 weight percent to about 7 weight percent or about 0.5 weight percent to about 6 weight percent or about 0.5 weight percent to about 5 weight percent or about 0.5 weight percent to about 4 weight percent. or about 0.5 weight percent to about 3 weight percent. The one or more corrosion inhibitors may be present in any amount defined by the endpoints selected from the following weight percents: 0.005, 0.02, 0.08, 0.1, 0.2, 0.25, 0.3, 0.4, 0.5, 0.7, 0.9, 1, 2, 3, 4, 5, 6, 7, 8, 9 and 10.

In some embodiments, the (v) one or more non-triazine corrosion inhibitors includes one or more of BZT, sorbitol, resorcinol, sebacic acid, glycerol and copper (II) nitrate. In some embodiments, these corrosion inhibitors are present (alone or in combination) between about 0.01 wt % and about 2 wt %. In some embodiments, these non-triazine corrosion inhibitors are present (alone or in combination) between about 0.2 wt % and about 1 wt %. In some embodiments, these corrosion inhibitors are present (alone or in combination) at about 0.5 wt %.

In some embodiments, the (v) one or more non-triazine corrosion inhibitors includes BZT. In one aspect of this embodiment, the solution includes about 0.1 wt % to about 1 wt % of BZT. In another aspect of this embodiment, the solution includes about 0.1 wt % of BZT. In another aspect of this embodiment, the solution includes about 0.5 wt % of BZT. In another aspect of this embodiment, the solution includes about 1.0 wt % of BZT.

In some embodiments, the (v) one or more non-triazine corrosion inhibitors includes sorbitol. In one aspect of this embodiment, the solution includes about 0.2 wt % to about 5 wt % of sorbitol. In one aspect of this embodiment, the solution includes about 0.2 wt % to about 3 wt % of sorbitol. In another aspect of this embodiment, the solution includes about 0.2 wt % of sorbitol. In another aspect of this embodiment, the solution includes about 0.5 wt % of sorbitol. In another aspect of this embodiment, the solution includes about 1.0 wt % of sorbitol. In another aspect of this embodiment, the solution includes about 1.5 wt % of sorbitol. In another aspect of this embodiment, the solution includes about 2.0 wt % of sorbitol. In another aspect of this embodiment, the solution includes about 2.5 wt % of sorbitol. In another aspect of this embodiment, the solution includes about 3.0 wt % of sorbitol. In another aspect of this embodiment, the solution includes about 3.5 wt % of sorbitol. In another aspect of this embodiment, the solution includes about 4.0 wt % of sorbitol. In another aspect of this embodiment, the solution includes about 4.5 wt % of sorbitol. In another aspect of this embodiment, the solution includes about 5.0 wt % of sorbitol.

In some embodiments, the (v) one or more non-triazine corrosion inhibitors includes resorcinol. In one aspect of this embodiment, the solution includes about 0.2 wt % to about 2 wt % of resorcinol. In one aspect of this embodiment, the solution includes about 0.2 wt % to about 4 wt % of resorcinol. In another aspect of this embodiment, the solution includes about 0.2 wt % of resorcinol. In another aspect of this embodiment, the solution includes about 0.5 wt % of resorcinol. In another aspect of this embodiment, the solution includes about 1.0 wt % of resorcinol. In another aspect of this embodiment, the solution includes about 1.5 wt % of resorcinol. In another aspect of this embodiment, the solution includes about 2.0 wt % of resorcinol. In another aspect of this embodiment, the solution includes about 2.5 wt % of resorcinol. In another aspect of this embodiment, the solution includes about 3.0 wt % of resorcinol. In another aspect of this embodiment, the solution includes about 3.5 wt % of resorcinol. In another aspect of this embodiment, the solution includes about 4.0 wt % of resorcinol.

In some embodiments, the (v) one or more non-triazine corrosion inhibitors includes glycerol. In one aspect of this embodiment, the solution includes about 0.2 wt % to about 1 wt % of glycerol. In another aspect of this embodiment, the solution includes about 0.2 wt % of glycerol. In another aspect of this embodiment, the solution includes about 0.5 wt % of glycerol. In another aspect of this embodiment, the solution includes about 1.0 wt % of glycerol.

In some embodiments, the (v) one or more non-triazine corrosion inhibitors includes sebacic acid. In one aspect of this embodiment, the solution includes about 0.2 wt % to about 1 wt % of sebacic acid. In another aspect of this embodiment, the solution includes about 0.2 wt % of sebacic acid. In another aspect of this embodiment, the solution includes about 0.5 wt % of sebacic acid. In another aspect of this embodiment, the solution includes about 1.0 wt % of sebacic acid.

In some embodiments, the (v) one or more non-triazine corrosion inhibitors includes copper nitrate. In one aspect of this embodiment, the solution includes about 0.005 wt % to about 0.5 wt % of copper nitrate. In another aspect of this embodiment, the solution includes about 0.01 wt % of copper nitrate. In another aspect of this embodiment, the solution includes about 0.2 wt % of copper nitrate. In another aspect of this embodiment, the solution includes about 0.5 wt % of copper nitrate.

In a further aspect, the solutions further optionally include, consist essentially of or consist of (v) two or more non-triazine corrosion inhibitor. In some embodiments, the (v) two or more non-triazine corrosion inhibitors includes one or more of BZT, sorbitol, resorcinol, 8-HQ, sebacic acid, glycerol, histidine, and copper (II) nitrate. In some embodiments, the (v) two or more non-triazine corrosion inhibitors includes BZT and one or more of sorbitol, resorcinol, 8-HQ, sebacic acid, glycerol, histidine, and copper (II) nitrate. In one embodiment, the (v) two or more non-triazine corrosion inhibitors includes BZT and sorbitol. In one embodiment, the (v) two or more non-triazine corrosion inhibitors includes BZT and copper (II) nitrate. In one embodiment, the (v) two or more non-triazine corrosion inhibitors includes BZT and resorcinol. In one embodiment, the (v) two or more non-triazine corrosion inhibitors includes BZT and 8-HQ. In one embodiment, the (v) two or more non-triazine corrosion inhibitors includes BZT and histidine. In one embodiment, the (v) two or more non-triazine corrosion inhibitors includes BZT and glycerol. In one embodiment, the (v) two or more non-triazine corrosion inhibitors includes BZT and sebacic acid.

### EXEMPLARY EMBODIMENTS

All values in the following exemplary embodiments are neat values unless otherwise indicated.

### Embodiment 1

In one embodiment, the disclosed and claimed solution includes, consist essentially of or consist of:
(i) one or more base component that includes, consist essentially of or consist of one or more of DMDPAH, TEAH, KOH, TMAH, ETMAH, choline hydroxide, monoethanolamine and combinations thereof;
(ii) one or more organic solvents that includes, consist essentially of or consist of one or more of DMSO, propylene glycol, diethylene glycol monoethyl ether, diethylene glycol monobutyl ether, triethylene glycol monomethyl ether, 3-methoxy-3-methyl-1-butanol and combinations thereof; and
(iii) one or more triazine derivative corrosion inhibitor that includes, consist essentially of or consist of one or more guanamine compounds of Formula 2:

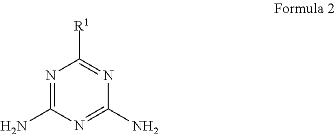

wherein R¹ is selected from a hydrogen atom, an oxygen-containing group, a hydroxyl group, a mercapto group, a nitrogen-containing group, an amine

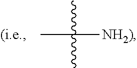

an amino group substituted with a C₁-C₁₀ alkyl group

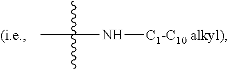

a carboxyl group, a phenyl group, a substituted phenyl group, an alkoxy group, a C₁ to C₂₀ linear alkyl group, a C₃ to C₂₀ branched alkyl group, a C₃ to C₁₀ cyclic alkyl group, a C₅ to C₁₂ aryl group, a C₂ to C₁₀ linear alkenyl group a C₃ to C₁₀ branched alkenyl group, a C₂ to C₁₀ linear alkynyl group, a C₃ to C₁₀ branched alkynyl group, a C₁ to C₂₀ linear alkyl group substituted with a halide and a C₁-C₂₀ alkyl substituted with

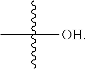 [SMILES: *O]

In a further aspect of this embodiment, the (i) one or more base component includes, consists essentially of or consists of DMDPAH. In a further aspect of this embodiment, the (i) one or more base component includes, consists essentially of or consists of TEAH. In a further aspect of this embodiment, the (i) one or more base component that includes, consists essentially of or consists KOH. In a further aspect of this embodiment, the (i) one or more base component includes, consists essentially of or consists of TMAH. In a further aspect of this embodiment, the (i) one or more base component includes, consists essentially of or consists of ETMAH. In a further aspect of this embodiment, the (i) one or more base component includes, consists essentially of or consists choline hydroxide. In a further aspect of this embodiment, the (ii) one or more organic solvents includes, consists essentially of or consists of DMSO. In a further aspect of this embodiment, the (ii) one or more organic solvents includes, consists essentially of or consists of propylene glycol. In a further aspect of this embodiment, the (ii) one or more organic solvents includes, consists essentially of or consists of diethylene glycol monoethyl ether. In a further aspect of this embodiment, the (ii) one or more organic solvents includes, consists essentially of or consists of diethylene glycol monobutyl ether. In a further aspect of this embodiment, the (ii) one or more organic solvents includes, consists essentially of or consists of triethylene glycol monomethyl ether. In a further aspect of this embodiment, the (ii) one or more organic solvents includes, consists essentially of or consists of 3-methoxy-3-methyl-1-butanol.

In a further aspect of this embodiment, the solution includes, consists essentially of or consist of water as a (iv) one or more secondary solvent. In a further aspect of this embodiment, the solution includes, consists essentially of or consist of resorcinol as a (v) one or more non-triazine corrosion inhibitor. In a further aspect of this embodiment, the solution includes, consists essentially of or consist of BZT as a (v) one or more non-triazine corrosion inhibitor. In a further aspect of this embodiment, the solution includes, consists essentially of or consist of sorbitol as a (v) one or more non-triazine corrosion inhibitor. In a further aspect of this embodiment, the solution includes, consists essentially of or consist of copper (II) nitrate as a (v) one or more non-triazine corrosion inhibitor. In a further aspect of this embodiment, the solution includes, consists essentially of or consist of 8-HQ as a (v) one or more non-triazine corrosion inhibitor. In a further aspect of this embodiment, the solution includes, consists essentially of or consist of one or more of resorcinol, BZT, sorbitol, 8-HQ and copper (II) nitrate as a (v) one or more non-triazine corrosion inhibitor. In a further aspect of this embodiment, the solution includes, consists essentially of or consist of two or more of resorcinol, BZT, sorbitol, 8-HQ and copper (II) nitrate as a (v) one or more non-triazine corrosion inhibitor.

### Embodiment 2

In another preferred embodiment, the disclosed and claimed solution includes, consist essentially of or consist of:
(i) one or more base component that includes, consist essentially of or consist of one or more of DMDPAH, TEAH, KOH, TMAH, ETMAH, choline hydroxide, monoethanolamine and combinations thereof;
(ii) one or more organic solvents that includes, consist essentially of or consist of one or more of DMSO, propylene glycol, diethylene glycol monoethyl ether, diethylene glycol monobutyl ether, triethylene glycol monomethyl ether, 3-methoxy-3-methyl-1-butanol and combinations thereof; and
(iii) one or more triazine derivative corrosion inhibitor that includes, consist essentially of or consist of a guanamine compound of Formula 3:

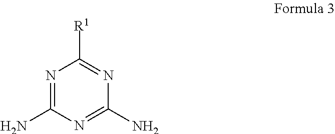

where R¹ is selected from hydrogen, an —OH group, a carboxyl group, a phenyl group, a substituted phenyl group, an amine, a C₁-C₆ linear alkyl group and a C₃-C₆ branched chain alky group.

In a further aspect of this embodiment, the R¹ in Formula 3 is hydrogen. In a further aspect of this embodiment, the R¹ in Formula 3 is an —OH group. In a further aspect of this embodiment, the R¹ in Formula 3 is a carboxyl group. In a further aspect of this embodiment, the R¹ in Formula 3 is a phenyl group. In a further aspect of this embodiment, the R¹ in Formula 3 is a substituted phenyl group. In a further aspect of this embodiment, the R¹ in Formula 3 is an amine. In a further aspect of this embodiment, the R¹ in Formula 3 is a C₁-C₆ linear alkyl group. In a further aspect of this embodiment, the R¹ in Formula 3 is a C₃-C₆ branched chain alky group.

In a further aspect of this embodiment, the (i) one or more base component includes, consists essentially of or consists of DMDPAH. In a further aspect of this embodiment, the (i) one or more base component includes, consists essentially of or consists of TEAH. In a further aspect of this embodiment, the (i) one or more base component that includes, consists essentially of or consists KOH. In a further aspect of this embodiment, the (i) one or more base component includes, consists essentially of or consists of TMAH. In a further aspect of this embodiment, the (i) one or more base component includes, consists essentially of or consists of ETMAH. In a further aspect of this embodiment, the (i) one or more base component includes, consists essentially of or consists choline hydroxide. In a further aspect of this embodiment, the (i) one or more base component includes, consists essentially of monoethanolamine. In a further aspect of this embodiment, the (ii) one or more organic solvents includes, consists essentially of or consists of DMSO. In a further aspect of this embodiment, the (ii) one or more organic solvents includes, consists essentially of or consists of propylene glycol. In a further aspect of this embodiment, the (ii) one or more organic solvents includes, consists essentially of or consists of diethylene glycol monoethyl ether. In a further aspect of this embodiment, the (ii) one or more organic solvents includes, consists essentially of or consists of diethylene glycol monobutyl ether. In a further aspect of this embodiment, the (ii) one or more organic solvents includes, consists essentially of or consists of triethylene glycol monomethyl ether. In a further aspect of this embodiment, the (ii) one or more organic solvents includes, consists essentially of or consists of 3-methoxy-3-methyl-1-butanol.

In a further aspect of this embodiment, the solution includes, consists essentially of or consist of water as a (iv) one or more secondary solvent. In a further aspect of this embodiment, the solution includes, consists essentially of or consist of resorcinol as a (v) one or more non-triazine corrosion inhibitor. In a further aspect of this embodiment, the solution includes, consists essentially of or consist of BZT as a (v) one or more non-triazine corrosion inhibitor. In a further aspect of this embodiment, the solution includes, consists essentially of or consist of sorbitol as a (v) one or more non-triazine corrosion inhibitor. In a further aspect of this embodiment, the solution includes, consists essentially of or consist of copper (II) nitrate as a (v) one or more non-triazine corrosion inhibitor. In a further aspect of this embodiment, the solution includes, consists essentially of or consist of one or more of resorcinol, BZT, sorbitol, 8-HQ and copper (II) nitrate as a (v) one or more non-triazine corrosion inhibitor. In a further aspect of this embodiment, the solution includes, consists essentially of or consist of two or more of resorcinol, BZT, sorbitol, 8-HQ and copper (II) nitrate as a (v) one or more non-triazine corrosion inhibitor.

### Embodiment 3

In another preferred embodiment, the disclosed and claimed solution includes, consist essentially of or consist of:
(i) one or more base component that includes, consist essentially of or consist of one or more of DMDPAH, TEAH, KOH, TMAH, ETMAH, choline hydroxide, monoethanolamine and combinations thereof;
(ii) one or more organic solvents that includes, consist essentially of or consist of one or more of DMSO, propylene glycol, diethylene glycol monoethyl ether, diethylene glycol monobutyl ether, triethylene glycol monomethyl ether, 3-methoxy-3-methyl-1-butanol and combinations thereof; and
(iii) one or more triazine derivative corrosion inhibitor that includes, consist essentially of or consist of benzoguanamine:

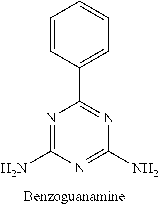 [SMILES: Nc1nc(N)nc(-c2ccccc2)n1]

In a further aspect of this embodiment, the (i) one or more base component includes, consists essentially of or consists of DMDPAH. In a further aspect of this embodiment, the (i) one or more base component includes, consists essentially of or consists of TEAH. In a further aspect of this embodiment, the (i) one or more base component that includes, consists essentially of or consists KOH. In a further aspect of this embodiment, the (i) one or more base component includes, consists essentially of or consists of TMAH. In a further aspect of this embodiment, the (i) one or more base component includes, consists essentially of or consists of ETMAH. In a further aspect of this embodiment, the (i) one or more base component includes, consists essentially of or consists choline hydroxide. In a further aspect of this embodiment, the (i) one or more base component includes, consists essentially of monoethanolamine. In a further aspect of this embodiment, the (ii) one or more organic solvents includes, consists essentially of or consists of DMSO. In a further aspect of this embodiment, the (ii) one or more organic solvents includes, consists essentially of or consists of propylene glycol. In a further aspect of this embodiment, the (ii) one or more organic solvents includes, consists essentially of or consists of diethylene glycol monoethyl ether. In a further aspect of this embodiment, the (ii) one or more organic solvents includes, consists essentially of or consists of diethylene glycol monobutyl ether. In a further aspect of this embodiment, the (ii) one or more organic solvents includes, consists essentially of or consists of triethylene glycol monomethyl ether. In a further aspect of this embodiment, the (ii) one or more organic solvents includes, consists essentially of or consists of 3-methoxy-3-methyl-1-butanol.

In a further aspect of this embodiment, the solution includes, consists essentially of or consist of water as a (iv) one or more secondary solvent. In a further aspect of this embodiment, the solution includes, consists essentially of or consist of resorcinol as a (v) one or more non-triazine corrosion inhibitor. In a further aspect of this embodiment, the solution includes, consists essentially of or consist of BZT as a (v) one or more non-triazine corrosion inhibitor. In a further aspect of this embodiment, the solution includes, consists essentially of or consist of sorbitol as a (v) one or more non-triazine corrosion inhibitor. In a further aspect of this embodiment, the solution includes, consists essentially of or consist of copper (II) nitrate as a (v) one or more non-triazine corrosion inhibitor. In a further aspect of this embodiment, the solution includes, consists essentially of or consist of two or more of resorcinol, BZT, sorbitol and copper (II) nitrate as a (v) one or more non-triazine corrosion inhibitor.

### Embodiment 4

In another preferred embodiment, the disclosed and claimed solution includes, consist essentially of or consist of:
(i) one or more base component that includes, consist essentially of or consist of about 2.6 wt % of DMDPAH and about 6 wt % of monocthanolamine;
(ii) one or more organic solvents that includes, consist essentially of or consist of about 80 wt % of DMSO and about 10.5 wt % of propylene glycol; and
(iii) one or more triazine derivative corrosion inhibitor that includes, consist essentially of or consist of about 0.75 wt % to about 1.0 wt % of benzoguanamine.

In a further aspect of this embodiment, the disclosed and claimed solution includes, consist essentially of or consist of about 0.8 wt % of benzoguanamine. In a further aspect of this embodiment, the disclosed and claimed solution includes, consist essentially of or consist of about 1 wt % of benzoguanamine. In a further aspect of this embodiment, the disclosed and claimed solution includes, consist essentially of or consist of one or more of resorcinol, 8-HQ, copper nitrate (e.g., ˜18.7 wt % copper nitrate solution; “NADA”), histidine and sorbitol. In a further aspect of this embodiment, the disclosed and claimed solution includes, consist essentially of or consist of about 0.1 wt % of resorcinol. In a further aspect of this embodiment, the disclosed and claimed solution includes, consist essentially of or consist of about 0.8 wt % of resorcinol. In a further aspect of this embodiment, a ratio of benzoguanamine to resorcinol is about 4:1 to about 1:4. In a further aspect of this embodiment, a ratio of benzoguanamine to resorcinol is about 4:1. In a further aspect of this embodiment, a ratio of benzoguanamine to resorcinol is about 3:1. In a further aspect of this embodiment, a ratio of benzoguanamine to resorcinol is about 2:1. In a further aspect of this embodiment, a ratio of benzoguanamine to resorcinol is about 1:1. In a further aspect of this embodiment, a ratio of benzoguanamine to resorcinol is about 1:2. In a further aspect of this embodiment, a ratio of benzoguanamine to resorcinol is about 1:3. In a further aspect of this embodiment, a ratio of benzoguanamine to resorcinol is about 1:4. In a further aspect of this embodiment, the disclosed and claimed solution includes, consist essentially of or consist of about 0.8 wt % of benzoguanamine and about 0.1 wt % of resorcinol. In a further aspect of this embodiment, the disclosed and claimed solution includes, consist essentially of or consist of about 0.8 wt % of benzoguanamine and about 0.8 wt % of resorcinol. In a further aspect of this embodiment, the disclosed and claimed solution includes, consist essentially of or consist of about 0.5 wt % of 8-HQ. In a further aspect of this embodiment, the disclosed and claimed solution includes, consist essentially of or consist of about 0.01 wt % of NADA. In a further aspect of this embodiment, the disclosed and claimed solution includes, consist essentially of or consist of about 0.3 wt % histidine. In a further aspect of this embodiment, the disclosed and claimed solution includes, consist essentially of or consist of about 1 wt % of sorbitol. In a further aspect of this embodiment, a ratio of benzoguanamine to sorbitol is about 4:1 to about 1:4. In a further aspect of this embodiment, a ratio of benzoguanamine to sorbitol is about 4:1. In a further aspect of this embodiment, a ratio of benzoguanamine to sorbitol is about 3:1. In a further aspect of this embodiment, a ratio of benzoguanamine to sorbitol is about 2:1. In a further aspect of this embodiment, a ratio of benzoguanamine to sorbitol is about 1:1. In a further aspect of this embodiment, a ratio of benzoguanamine to sorbitol is about 1:2. In a further aspect of this embodiment, a ratio of benzoguanamine to sorbitol is about 1:3. In a further aspect of this embodiment, a ratio of benzoguanamine to sorbitol is about 1:4. In a further aspect of this embodiment, the disclosed and claimed solution includes, consist essentially of or consist of about 0.15 wt % of copper nitrate. In a further aspect of this embodiment, a ratio of benzoguanamine to copper nitrate is about 4:1 to about 1:4. In a further aspect of this embodiment, a ratio of benzoguanamine to copper nitrate is about 4:1. In a further aspect of this embodiment, a ratio of benzoguanamine to copper nitrate is about 3:1. In a further aspect of this embodiment, a ratio of benzoguanamine to copper nitrate is about 2:1. In a further aspect of this embodiment, a ratio of benzoguanamine to copper nitrate is about 1:1. In a further aspect of this embodiment, a ratio of benzoguanamine to copper nitrate is about 1:2. In a further aspect of this embodiment, a ratio of benzoguanamine to copper nitrate is about 1:3. In a further aspect of this embodiment, a ratio of benzoguanamine to copper nitrate is about 1:4.

### Embodiment 5

In another preferred embodiment, the disclosed and claimed solution includes, consist essentially of or consist of:
(i) one or more base component that includes, consist essentially of or consist of about 1.75 wt % to about 2.0 wt % of KOH;
(ii) one or more organic solvents that includes, consist essentially of or consist of about 55 wt % to about 97.5 wt % of diethylene glycol monoethyl ether; and
(iii) one or more triazine derivative corrosion inhibitor that includes, consist essentially of or consist of about 0.25 wt % to about 0.75 wt % benzoguanamine.

In a further aspect of this embodiment, the disclosed and claimed solution includes, consist essentially of or consist of about 10 wt % to about 45 wt % of water. In a further aspect of this embodiment, the disclosed and claimed solution includes, consist essentially of or consist of up to about 41 wt % of water. In a further aspect of this embodiment, the disclosed and claimed solution includes, consist essentially of or consist of a balance (i.e., the remainder) of water. In a further aspect of this embodiment, the solution includes, consist essentially of or consist of about 1.8 wt % of KOH. In a further aspect of this embodiment, the solution includes, consist essentially of or consist of about 57.5 wt % of diethylene glycol monoethyl ether. In a further aspect of this embodiment, the solution includes, consist essentially of or consist of about 72.5 wt % of diethylene glycol monoethyl ether. In a further aspect of this embodiment, the solution includes, consist essentially of or consist of about 82.5 wt % of diethylene glycol monoethyl ether. In a further aspect of this embodiment, the solution: includes, consist essentially of or consist of about 97.5 wt % of diethylene glycol monoethyl ether. In a further aspect of this embodiment, the solution includes, consist essentially of or consist of about 0.5 wt % of benzoguanamine. In a further aspect of this embodiment, the disclosed and claimed solution is substantially free of water. In a further aspect of this embodiment, the disclosed and claimed solution includes, consist essentially of or consist of about 15 wt % of water. In a further aspect of this embodiment, the disclosed and claimed solution includes, consist essentially of or consist of about 25 wt % of water. In a further aspect of this embodiment, the disclosed and claimed solution includes, consist essentially of or consist of about 40 wt % of water.

### Embodiment 6

In another preferred embodiment, the disclosed and claimed solution includes, consist essentially of or consist of:
(i) one or more base component that includes, consist essentially of or consist of about 2.5 wt % to about 3.0 wt % of DMDPAH;
(ii) one or more organic solvents that includes, consist essentially of or consist of about 10.5 wt % of propylene glycol and about 45 wt % to about 86.5 wt % of diethylene glycol monoethyl ether; and
(iii) one or more triazine derivative corrosion inhibitor that includes, consist essentially of or consist of about 0.25 wt % to about 0.75 wt % benzoguanamine.

In a further aspect of this embodiment, the disclosed and claimed solution includes, consist essentially of or consist of about 10 wt % to about 45 wt % of water. In a further aspect of this embodiment, the disclosed and claimed solution includes, consist essentially of or consist of up to about 40 wt % of water. In a further aspect of this embodiment, the disclosed and claimed solution includes, consist essentially of or consist of a balance (i.e., the remainder) of water. In a further aspect of this embodiment, the solution includes, consist essentially of or consist of about 2.6 wt % of DMDPAH. In a further aspect of this embodiment, the solution includes, consist essentially of or consist of about 46.4 wt % of diethylene glycol monoethyl ether. In a further aspect of this embodiment, the solution includes, consist essentially of or consist of about 61.4 wt % of diethylene glycol monoethyl ether. In a further aspect of this embodiment, the solution includes, consist essentially of or consist of about 61.9 wt % of diethylene glycol monoethyl ether. In a further aspect of this embodiment, the solution includes, consist essentially of or consist of about 71.4 wt % of diethylene glycol monoethyl ether. In a further aspect of this embodiment, the solution includes, consist essentially of or consist of about 86.4 wt % of diethylene glycol monoethyl ether. In a further aspect of this embodiment, the solution includes, consist essentially of or consist of about 0.5 wt % of benzoguanamine. In a further aspect of this embodiment, the disclosed and claimed solution is substantially free of water. In a further aspect of this embodiment, the disclosed and claimed solution is free of water. In a further aspect of this embodiment, the disclosed and claimed solution includes, consist essentially of or consist of about 15 wt % of water. In a further aspect of this embodiment, the disclosed and claimed solution includes, consist essentially of or consist of about 25 wt % of water. In a further aspect of this embodiment, the disclosed and claimed solution includes, consist essentially of or consist of about 40 wt % of water.

### Embodiment 7

In another preferred embodiment, the disclosed and claimed solution includes, consist essentially of or consist of:
(i) one or more base component that includes, consist essentially of or consist of about 10 wt % to about 15 wt % of TEAH;
(ii) one or more organic solvents that includes, consist essentially of or consist of about 45 wt % to about 65 wt % of diethylene glycol monoethyl ether; and
(iii) one or more triazine derivative corrosion inhibitor that includes, consist essentially of or consist of about 0.25 wt % to about 0.75 wt % benzoguanamine.

In a further aspect of this embodiment, the disclosed and claimed solution includes, consist essentially of or consist of about 20 wt % to about 40 wt % of water. In a further aspect of this embodiment, the solution includes, consist essentially of or consist of about 10 wt % to about 13.5 wt % of TEAH. In a further aspect of this embodiment, the solution includes, consist essentially of or consist of about 13 wt % of TEAH. In a further aspect of this embodiment, the solution includes, consist essentially of or consist of about 46.5 wt % of diethylene glycol monoethyl ether. In a further aspect of this embodiment, the solution includes, consist essentially of or consist of about 62.5 wt % of diethylene glycol monoethyl ether. In a further aspect of this embodiment, the solution includes, consist essentially of or consist of about 0.5 wt % of benzoguanamine. In a further aspect of this embodiment, the disclosed and claimed solution is substantially free of water. In a further aspect of this embodiment, the disclosed and claimed solution includes, consist essentially of or consist of about 24 wt % of water. In a further aspect of this embodiment, the disclosed and claimed solution includes, consist essentially of or consist of about 40 wt % of water.

### Embodiment 8

In another preferred embodiment, the disclosed and claimed solution includes, consist essentially of or consist of:
(i) one or more base component that includes, consist essentially of or consist of about 10 wt % to about 15 wt % of choline hydroxide;
(ii) one or more organic solvents that includes, consist essentially of or consist of about 45 wt % to about 75 wt % of diethylene glycol monoethyl ether; and
iii) one or more triazine derivative corrosion inhibitor that includes, consist essentially of or consist of about 0.25 wt % to about 0.75 wt % benzoguanamine.

In a further aspect of this embodiment, the disclosed and claimed solution includes, consist essentially of or consist of about 15 wt % to about 45 wt % of water. In a further aspect of this embodiment, the solution includes, consist essentially of or consist of about 11.25 wt % of choline hydroxide. In a further aspect of this embodiment, the solution includes, consist essentially of or consist of about 48.25 wt % of diethylene glycol monoethyl ether. In a further aspect of this embodiment, the solution includes, consist essentially of or consist of about 63.25 wt % of diethylene glycol monoethyl ether. In a further aspect of this embodiment, the solution includes, consist essentially of or consist of about 73.25 wt % of diethylene glycol monoethyl ether. In a further aspect of this embodiment, the solution includes, consist essentially of or consist of about 0.5 wt % of benzoguanamine. In a further aspect of this embodiment, the disclosed and claimed solution is substantially free of water. In a further aspect of this embodiment, the disclosed and claimed solution includes, consist essentially of or consist of about 15 wt % of water. In a further aspect of this embodiment, the disclosed and claimed solution includes, consist essentially of or consist of about 25 wt % of water. In a further aspect of this embodiment, the disclosed and claimed solution includes, consist essentially of or consist of about 40 wt % of water.

### Embodiment 9

In another preferred embodiment, the disclosed and claimed solution includes, consist essentially of or consist of:
(i) one or more base component that includes, consist essentially of or consist of about 10 wt % to about 15 wt % of TEAH;
(ii) one or more organic solvents that includes, consists essentially of or consists of about 62.5 wt % of DMSO, diethylene glycol monoethyl ether, diethylene glycol monobutyl ether, triethylene glycol monomethyl ether, 3-methoxy-3-methyl-1-butanol;
(iii) one or more triazine derivative corrosion inhibitor that includes, consist essentially of or consist of about 0.5 wt % benzoguanamine;
(iv) one or more secondary solvent that includes, consist essentially of or consist of about 24 wt % of water.

In a further aspect of this embodiment, the (ii) one or more organic solvents includes, consists essentially of or consists of about 62.5 wt % of DMSO. In a further aspect of this embodiment, the (ii) one or more organic solvents includes, consists essentially of or consists of about 62.5 wt % of diethylene glycol monoethyl ether. In a further aspect of this embodiment, the (ii) one or more organic solvents includes, consists essentially of or consists of about 62.5 wt % of diethylene glycol monobutyl ether. In a further aspect of this embodiment, the (ii) one or more organic solvents includes, consists essentially of or consists of about 62.5 wt % of triethylene glycol monomethyl ether. In a further aspect of this embodiment, the (ii) one or more organic solvents includes, consists essentially of or consists of about 62.5 wt % of 3-methoxy-3-methyl-1-butanol.

In a further aspect of this embodiment, the solution includes, consist essentially of or consist of about 10 wt % to about 13.5 wt % of TEAH. In a further aspect of this embodiment, the solution includes, consist essentially of or consist of about 13 wt % of TEAH.

### Embodiment 10

In another preferred embodiment, the disclosed and claimed solution includes, consist essentially of or consist of:
(i) one or more base component that includes, consist essentially of or consist of one of about 1.5 wt % to about 2.0 wt % of KOH, about 2.5 wt % to about 3.0 wt % of DMDPAH, 10 wt % to about 15 wt % of TEAH, 5 wt % to about 15 wt % of TMAH, 5 wt % to about 15 wt % of ETMAH and about 10 wt % to about 13 wt % of choline hydroxide;
(ii) one or more organic solvents that includes, consists essentially of or consists of about 60 wt % to about 73 wt % of diethylene glycol monoethyl ether;
(iii) one or more triazine derivative corrosion inhibitor that includes, consist essentially of or consist of about 0.5 wt % benzoguanamine;
(iv) one or more secondary solvent that includes, consist essentially of or consist of about 24 wt % to about 25 wt % of water.

In a further aspect of this embodiment, the (ii) one or more organic solvents further includes, consists essentially of or consists of about 10.5 wt % of propylene glycol. In a further aspect of this embodiment, the (i) one or more base component that includes, consist essentially of or consist of about 1.8 wt % of KOH. In a further aspect of this embodiment, the (i) one or more base component that includes, consist essentially of or consist of about 2.6 wt % of DMDPAH. In a further aspect of this embodiment, the (i) one or more base component that includes, consist essentially of or consist of about 10 wt % to about 13.5 wt % of TEAH. In a further aspect of this embodiment, the (i) one or more base component that includes, consist essentially of or consist of about 13 wt % of TEAH. In a further aspect of this embodiment, the (i) one or more base component that includes, consist essentially of or consist of about 8 wt % of TMAH. In a further aspect of this embodiment, the (i) one or more base component that includes, consist essentially of or consist of about 8 wt % of ETMAH. In a further aspect of this embodiment, the (i) one or more base component that includes, consist essentially of or consist of about 11.25 wt % of choline hydroxide.

### Other Optional or Excluded Ingredients

In some embodiments, the disclosed and claimed solutions are substantially free of, alternatively free of (as those terms were defined earlier) one or more than one of the following in any combination: nitrogen containing solvents, bis-choline salts, tri-choline salts, oxoammonium compounds, hydroxylamines and derivatives thereof, hydrogen peroxide, oxidants, surfactants, sulfur-containing compounds, inorganic acids, organic acid such as carboxylic acids and combinations thereof.

In some embodiments, the compositions disclosed herein are formulated to be substantially free or free of at least one of the following chemical compounds: alkyl thiols, and organic silanes.

In some embodiments, the disclosed and claimed solutions are formulated to be substantially free or free of one or more of the following: halide-containing compound, for example it may be substantially free or free of one or more of the following: fluoride-, bromine-, chlorine- or iodine-containing compounds.

In some embodiments, the disclosed and claimed subject matter is free of amidoxime compounds. In some embodiments, the disclosed and claimed subject matter is free of metal-containing compounds.

In some embodiments, the disclosed and claimed solutions are substantially free or free of sulfonic acid and/or phosphoric acid and/or sulfuric acid and/or nitric acid and/or hydrochloric acid.

In some embodiments, the disclosed and claimed solutions are substantially free or free of one or more of ethyl diamine, sodium-containing compounds and/or calcium-containing compounds and/or manganese-containing compounds or magnesium-containing compounds and/or chromium-containing compounds and/or sulfur-containing compounds and/or silane-containing compounds and/or phosphorus-containing compounds.

In some embodiments, the disclosed and claimed solutions are substantially free of or free of surfactants.

In some embodiments, the disclosed and claimed solutions are substantially free or free of amphoteric salts, and/or cationic surfactants, and/or anionic surfactants, and/or zwitterionic surfactants, and/or non-ionic surfactants.

In some embodiments, the disclosed and claimed solutions are free of or free of imidizoles, and/or anhydrides.

In some embodiments, the disclosed and claimed solutions are substantially free of or free of pyrrolidones, and/or acetamides.

In some embodiments, the disclosed and claimed solutions are substantially free of or free of peroxy-compounds, and/or peroxides, and/or persulfates, and/or percarbonates, and acids thereof, and salts thereof.

In some embodiments, the disclosed and claimed solutions are substantially free of or free of iodates, and/or perboric acid, and/or percarbonates, and/or peroxyacids, and/or cerium compounds, and/or cyanides, and/or periodic acid and/or ammonium molybdate, and/or ammonia and/or abrasives.

In some embodiments, the disclosed and claimed solutions are substantially free of or free of copper salt(s). In some embodiments, the disclosed and claimed solutions are substantially free of or free of sugar alcohol(s). In some embodiments, the disclosed and claimed solutions are substantially free of or free of copper salt(s) and sugar alcohol(s).

### Methods of Use

The disclosed and claimed subject matter further includes a method of removing, in whole or on part, one or more photoresists or etch residue or similar materials from a substrate using one or of the disclosed and claimed photoresist stripper and etch residue remover solutions. As noted above, the disclosed and claimed photoresist stripper and etch residue remover solutions can be used to remove polymeric resist materials present in a single layer or certain types of bilayer resists. Utilizing the methods taught below, a single layer of polymeric resist can be effectively removed from a standard wafer having a single polymer layer. The same methods can also be used to remove a single polymer layer from a wafer having a bilayer composed of a first inorganic layer and a second or outer polymer layer. Finally, two polymer layers can be effectively removed from a wafer having a bilayer composed of two polymeric layers.

In one aspect of this embodiment, the process or method for removing a photoresist or etch residue from a substrate includes the steps of:
(i) contacting the substrate with one or more of the photoresist stripper and etch residue remover solutions for a time sufficient to remove a desired amount of the photoresist or similar material,
(ii) removing the substrate from the solution,
(iii) rinsing the solution from the substrate with DI water or a solvent, and
(iv) optionally drying the substrate.

In one embodiment, step (i) includes immersing the substrate one or more of the photoresist stripper and etch residue remover solutions and optionally agitating the substrate to facilitate photoresist removal. Such agitation can be affected by mechanical stirring, circulating or by bubbling an inert gas through the composition.

In one embodiment, step (ii) includes rinsing the substrate with water or an alcohol. In one aspect of this embodiment, DI water is a preferred form of water. In another aspect of this embodiment, isopropanol (IPA) is a preferred solvent. In another aspect of this embodiment, components subject to oxidation are or can be rinsed under an inert atmosphere.

Utilizing the above methods (as well as variants thereof), the disclosed and claimed photoresist stripper and etch residue remover solutions can be used for removal of thick and thin positive or negative tone photoresists. Thick photoresists may be a resist of from about 5 μm to about 100 μm or more, or about 15 μm to 100 μm, or from about 20 μm to about 100 μm in advanced packaging applications for semiconductor devices. In other cases, the chemical solutions may be used to remove photoresist from about 0.1 μm to about 100 μm or more, or about 0.2 μm to 100 μm, or from about 0.3 μm to about 100 μm.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

All materials used in this patent were purchased from and/or are available from Sigma Aldrich and were used in the formulations as received. Amounts of materials in all of the tables are reported as wt % values and reflect “neat” values where appropriate unless indicated otherwise. The balance of the formulation weights is from water present in the raw materials.

Testing was performed using blanket Cu wafer. For the immersion process, three coupon-sized samples of semiconductor wafers were processed in beakers. Beakers were filled with 100 grams of a stripping composition and heated to the target temperature. When the stripping composition was at the target temperature of 70° C., three coupons were placed in a holder in the beaker, and slight agitation was provided by a stir bar. Temperature was maintained at the process temperature in the table throughout the process. After a total processing time of 10-30 minutes, the coupons were removed from the beaker, rinsed with DI water and IPA, and dried with a stream of nitrogen.

Cu etch rates are determined by measuring film thickness using CDE four-point probe RESMAP before and after processing in the formulations. Typical starting layer thickness was 1000 Å for copper substrates. Copper substrates were processed in the prepared formulations at 70° C. with different stirring rates for 10-30 minutes and then the copper substrates were rinsed with water and dried by lowing nitrogen gas.

The follow abbreviations are used in the various compositions in the tables below:

| Abbreviation | Full name |
|---|---|
| KOH | Potassium Hydroxide |
| NaOH | Sodium Hydroxide |
| TMAH | Tetramethyl ammonium hydroxide |
| TEAH | Tetraethyl ammonium hydroxide |
| DMDPAH | Dimethyl dipropyl ammonium hydroxide |
| BA | Benzyl amine |
| DB | Diethylene Glycol Monobutyl Ether |
| DE | Diethylene Glycol Monoethyl Ether |
| MMB | 3-Methoxy-3-Methyl-1-Butanol |
| PG | Propylene Glycol |
| TEGME | Triethylene Glycol Monomethyl Ether |
| BZT | Benzotriazole |
| MEA | Monoethanolamine |
| NMDEA | N-methyldiethanolamine |
| BZG | Benzoguanamine |
| 8-HQ | 8-Hydroxy Quinoline |
| CI | Copper inhibitor |
| Res | Resorcinol |
| His | Histidine |
| e/r | Etch rate |

Amounts of materials in all of the tables are reported as wt % values and reflect “neat” values where appropriate unless indicated otherwise. All listed ingredients for the exemplary and comparative formulations total 100 wt %. Comparative examples are free of the guanamine (e.g., BZG) corrosion inhibitor.

### Non-Aqueous Examples and Comparatives

Formulations 1 and 2 were prepared by combining the following ingredients:

TABLE 1

| Ingredient | CAS# | 1 (wt %) | 2 (wt %) |
|---|---|---|---|
| DMSO | 67-68-5 | 79.9 | 79.3 |
| DMDPAH | 836597-65-0 | 2.6 | 2.6 |
| PG | 57-55-6 | 10.5 | 10.5 |
| MEA | 141-43-5 | 6 | 6 |
| BZG | 91-76-9 | 1 | 0.8 |
| Resorcinol | 108-46-3 | — | 0.8 |

A stock formulation comprised 80.9% DMSO, 6.0% monoethanolamine and 13.10% DMDPAH +PG. Different copper inhibitors were added to the base formulation in various different concentrations to test their protection for copper etch compared to Formulation 1. The copper etch rates was tested at 70° C. for 20 min at two stirring rates, 100 rpm and 400 rpm.

Table 2 shows among tested inhibitors, 2,4-diamino-6-phenyl-1,3,5-triazine (benzoguanamine) and melamine showed obviously low copper etch rates at different stirring rates. The formulations containing these two inhibitors did not show any color change. Cu surface also did not show the color change. Higher concentrations of these two inhibitors were also tested and list in Table 3. The results clearly showed these two inhibitors had good copper inhibitors in a wide concentration range. While resorcinol and catechol both showed low copper etch rates at certain concentrations, their formulations did show a color change to dark, suggesting the instability of those inhibitors.

TABLE 2

| | E.R. Å/cycle @ 100 RPM, 70° C. | | | E.R. Å/cycle @ 400 RPM, 70° C. | | |
|---|---|---|---|---|---|---|
| Inhibitors | 0.5 wt % | 1.0 wt % | 2.0 wt % | 0.5 wt % | 1.0 wt % | 2.0 wt % |
| Resorcinol | 14.6 ± 1.4 | 16.1 ± 2.1 | 19.1 ± 4.7 | 32.4 ± 0.1 | 26.8 ± 0.9 | 74.3 ± 1.5 |
| Catechol | 16.5 ± 0.4 | 30.6 ± 1.7 | 133.2 ± 0 | 41.8 ± 2.1 | 71.7 ± 3.6 | 129.8 ± 0 |
| Tert-Butyl | 21.4 ± 2.1 | 33.9 ± 0.5 | 71.0 ± 1.7 | 57.4 ± 1.2 | 76.3 ± 4.1 | 129.1 ± 0.1 |
| Catechol | | | | | | |
| Sorbitol | 49.1 ± 6.7 | 71.3 ± 7.1 | 68.3 ± 3.8 | 24.6 ± 7.0 | 78.5 ± 10.0 | 107.6 ± 4.1 |
| Maltitol | 70.7 ± 5.4 | 62.7 ± 8 | 78.6 ± 5.1 | 81.6 ± 8.5 | 85.9 ± 7.2 | 94.9 ± 6.7 |
| Xylitol | 62.6 ± 7.4 | 55.7 ± 4.5 | 76.2 ± 4.5 | 96.5 ± 3.9 | 87.0 ± 6.9 | 106.5 ± 3.2 |
| 1H-Benzotriazole | 49.4 ± 6.4 | 92.8 ± 2.9 | 106.4 ± 7.2 | 85.9 ± 2.0 | 114.0 ± 5.9 | 132.4 ± 2.0 |
| Benzotriazole-5- | 61.1 ± 5.5 | 44.6 ± 2.4 | 74.5 ± 4.9 | 47.0 ± 7.9 | 69.2 ± 5.5 | 130.7 ± 0.2 |
| Carboxylic | | | | | | |
| 5-Methyl-1H- | 54.0 ± 0.2 | 49.2 ± 8.9 | 79.5 ± 8.2 | 112.4 ± 9.7 | 109.9 ± 7.0 | 134.5 ± 0 |
| Benzotriazole | | | | | | |
| Histidine | 45.3 ± 3.4 | 41.9 ± 3.6 | 74.1 ± 4.5 | 84.7 ± 5.7 | 92.8 ± 9.7 | 131.4 ± 0.9 |
| Tryptophan | 77.1 ± 3.5 | 93.3 ± 8.9 | 127.2 ± 3.6 | 121.6 ± 1.2 | 131.1 ± 0.9 | 132.5 ± 1.6 |
| 8-HQ | 26.9 ± 2.5 | 22.8 ± 1.1 | 32.9 ± 1.7 | 14.3 ± 1.1 | 15.9 ± 0.5 | 61.7 ± 2.4 |
| 5-Amino-1,3,4- | 44.8 | 35.3 | — | 51 | 47.8 | — |
| thiadiazole-2-thiol | | | | | | |
| BZG | 17.3 | 13.0 | — | 15 | 9.78 | — |
| Melamine* | 23.8 | 27.7 | — | 28.2 | 31.8 | — |
| Adenosine | 55.2 | 43.1 | — | 59.4 | 51.9 | — |
| 2,4-Diamino-6- | 58.3 | 107 | — | 77.1 | 129 | — |
| hydroxy | | | | | | |
| pyrimidine* | | | | | | |
| Theophylline-7- | 46.7 | 110 | — | 82.3 | 128 | — |
| acetic acid | | | | | | |
| Base Formulation | 58.1 ± 11.0 | | | 97.6 ± 11.9 | | |
| (no CI; balance | | | | | | |
| DMSO) | | | | | | |

TABLE 3

| | | Etch rate @ 70° C., Å/min | |
|---|---|---|---|
| Base Formulation + CI | Increasing CI, wt % | 100 RPM | 400 RPM |
| Base Formulation | None | 29.52 ± 0.63 | 99.2 ± 8.1 |
| BZG | 2 | 5.8 ± 0.5 | 9.1 ± 1.5 |
| | 4 | 5.5 ± 1.1 | 8.8 ± 3.2 |
| Melamine | 0.25 | 20.2 ± 0.8 | 29.9 ± 3.6 |
| | 2 | 15.0 ± 0.3 | 23.4 ± 1.1 |

Copper salts were also tested as copper inhibitors and the results were shown in Table 4. Clearly copper salts were also good copper etch inhibitors. However, after processing, copper surface color changed to dark color suggesting their adsorption on copper surface. Also, their formulations showed precipitations with time, more clearly with high concentration of copper salts. The instability of copper salts as copper inhibitors was shown in Table 4. Copper etch rates gradually increased with aging time for copper nitrate while for benzoguanamine no significant change in copper etch rates was observed and no color change on copper surface was observed.

TABLE 4

Cu etch rate @ 70° C., Å/min

| Shelf time @ 50° C. | Copper Nitrate | BZG |
|---|---|---|
| 0 week | 8.22 ± 2 | 3.72 ± 0.68 |
| 1 week | 10.18 ± 2.44 | 4.44 ± 0.38 |
| 2 weeks | 18.58 ± 1.78 | 7.35 ± 0.37 |
| 3 weeks | 18.08 ± 3.44 | 8.37 ± 0.64 |
| 4 weeks | 14.50 ± 1.45 | 5.77 ± 0.56 |

Combination of other inhibitors with benzoguanamine was also tested for the prevention of copper etch as shown in Table 5. The results showed by combination of other inhibitors with benzoguanamine, copper etch rates were clearly decreased. Among those inhibitors, resorcinol combined with benzoguanamine showed the lowest copper etch rates.

TABLE 5

| Base Formulation + CI | CI, wt % | Etch rate 70° C., Å/min |
|---|---|---|
| BZG | 1 | 10.5 ± 1.4 |
| 8-HQ | 0.5 | 21.1 ± 1.7 |
| BZG + 8-HQ | 1/0.5 | 7.8 ± 0.7 |
| NADA | 0.01 | 13.4 ± 1.4 |
| BZG + NADA | 1/0.01 | 3.9 ± 0.4 |
| Resorcinol | 0.8 | 4.2 ± 0.3 |
| BZG + Res | 0.8/0.8 | 0.39 ± 0.09 |
| Histidine | 0.3 | 13.4 ± 1.5 |
| BZG + His | 1/0.3 | 5.5 ± 0.7 |

The copper etch rates for the combination of (0.8 wt %) benzoguanamine and (0.8 wt %) resorcinol was also tested in an accelerated aging tests at 50° C. as shown in Table 6. As can be see, the copper etch rates did not show significant change with aging time which demonstrates the stable copper inhibition behavior of benzoguanamine.

TABLE 6
Formulation 2

| Shelf time @ 50° C. | Cu Etch rate @ 70 C., Å/min |
|---|---|
| 0 week | 0.56 ± 0.24 |
| 1 week | 0.92 ± 0.33 |
| 2 weeks | 1.05 ± 0.07 |
| 3 weeks | 0.68 ± 0.08 |
| 4 weeks | 0.64 ± 0.11 |

Table 7 shows the etch rates on other metals from using Formulation 2.

TABLE 7

| Metal | Etch rate at 70° C. and 20 min, Å/min |
|---|---|
| Al | 1.8 ± 0.8 |
| Cu | 1.3 ± 0.4 |
| Ni | 0.03 ± 0.01 |
| TiW | 0.08 ± 0.01 |
| Au | 0.5 ± 0.1 |
| Sn | 0.32 ± 0.01 |
| Ti | 0.21 ± 0.03 |

### Examples and Comparatives Including Water

Formulations including water were prepared by combining different bases as set forth in Tables 8 (KOH), Table 9 (DMDPAH), Table 10 (TEAH), Table 11 (TEAH) and Table 12 (Various).

TABLE 8

| Component | CAS# | 1 | 2 | 3 | 4 | 5 |
|---|---|---|---|---|---|---|
| KOH Flake | 1310-58-3 | 1.8 | 1.8 | 1.8 | 1.8 | 1.8 |
| DE Solvent | 111-90-0 | 97.5 | 82.5 | 72.5 | 57.5 | 73 |
| Water | 7732-18-5 | 0.2* | 15.2* | 25.2* | 40.2* | 25.2* |
| BZG | 91-76-9 | 0.5 | 0.5 | 0.5 | 0.5 | 0 |

| Process Conditions | 10 min @70 ° C. | | | | |
|---|---|---|---|---|---|
| Cu e/r | 1.5 ± 0.1 | 3.2 ± 0.5 | 1.52 ± 0.05 | 1.0 ± 0.5 | 34.4 ± 6.0 |

*Includes estimated 0.2 wt % from KOH flake (90%).

TABLE 9

| Component | CAS # | 6 | 7 | 8 | 9 | 10 |
|---|---|---|---|---|---|---|
| DMDPAH | 836597-65-0 | 2.6 | 2.6 | 2.6 | 2.6 | 2.6 |
| PG | 57-55-6 | 10.5 | 10.5 | 10.5 | 10.5 | 10.5 |
| DE Solvent | 111-90-0 | 86.4 | 71.4 | 61.4 | 46.4 | 61.9 |
| Water | 7732-18-5 | 0 | 15 | 25 | 40 | 25 |
| BZG | 91-76-9 | 0.5 | 0.5 | 0.5 | 0.5 | 0 |

| Process Conditions | 10 min @70° C. | | | | |
|---|---|---|---|---|---|
| Cu e/r | 0.11 ± 0.09 | 0.5 ± 0.3 | 0.69 ± 0.02 | 0.9 ± 0.1 | 11.9 ± 1.5 |

TABLE 10

| Component | CAS | 11 | 12 | 13 |
|---|---|---|---|---|
| TEAH | 77-98-5 | 13 | 13 | 13 |
| DE Solvent | 111-90-0 | 63 | 62.5 | 46.5 |
| Water | 7732-18-5 | 24 | 24 | 40 |
| BZG | 91-76-9 | 0 | 0.5 | 0.5 |

| Process Conditions | 10 min @70° C. | | |
|---|---|---|---|
| Cu e/r | 5.2 ± 2.1 | 0.62 ± 0.08 | 1.01 ± 0.08 |

TABLE 11

| Component | CAS | 11 | 12 | 15 | 16 | 17 | 18 | 19 | 20 | 21 | 22 |
|---|---|---|---|---|---|---|---|---|---|---|---|
| TEAH | 77-98-5 | 13 | 13 | 13 | 13 | 13 | 13 | 13 | 13 | 13 | 13 |
| Water | 7732-18-5 | 24 | 24 | 24 | 24 | 24 | 24 | 24 | 24 | 24 | 24 |
| DE Solvent | 111-90-0 | 63 | 62.5 | — | — | — | — | — | — | — | — |
| DB Solvent | 112-34-5 | — | — | 63 | 62.5 | — | — | — | — | — | — |
| TEGME | 112-35-6 | — | — | — | — | 63 | 62.5 | — | — | — | — |
| MMB | 56539-66-3 | — | — | — | — | — | — | 63 | 62.5 | — | — |
| DMSO | 67-68-5 | — | — | — | — | — | — | — | — | 63 | 62.5 |
| BZG | 91-76-9 | — | 0.5 | — | 0.5 | — | 0.5 | — | 0.5 | — | 0.5 |

| Process Conditions | 10 min @70 ° C. | | | | | | | | | |
|---|---|---|---|---|---|---|---|---|---|---|
| Cu e/r | 5.2 ± | 0.62 ± | 3.10 ± | 0.2 ± | 4.59 ± | 0.85 ± | 13.07 ± | 0.61 ± | 13.17 ± | 0.10 ± |
| | 2.1 | 0.08 | 0.6 | 0.1 | 0.62 | 0.09 | 0.85 | 0.04 | 2.76 | 0.03 |

TABLE 12

| Component | CAS# | 5 | 3 | 10 | 8 | 11 | 12 |
|---|---|---|---|---|---|---|---|
| KOH Flake | 1310-58-3 | 1.8 | 1.8 | — | — | — | — |
| DMDPAH | 836597-65-0 | — | — | 2.6 | 2.6 | — | — |
| TEAH | 77-98-5 | — | — | — | — | 13 | 13 |
| Propylene Glycol | 57-55-6 | — | — | 10.5 | 10.5 | — | — |
| DE Solvent | 111-90-0 | 73 | 72.5 | 61.9 | 61.4 | 63 | 62.5 |
| Water | 7732-18-5 | 25.2* | 25.2* | 25 | 25 | 24 | 24 |
| BZG | 91-76-9 | — | 0.5 | — | 0.5 | — | 0.5 |

| Process Conditions | 10 min @70° C. | | | | | |
|---|---|---|---|---|---|---|
| Cu e/r | 34.4 ± 6.0 | 1.52 ± 0.05 | 11.9 ± 1.5 | 0.69 ± 0.02 | 5.2 ± 2.1 | 0.62 ± 0.08 |

*Includes estimated 0.2 wt % from KOH flake (90%).

### Analysis of Example Formulations: Corrosion Inhibitors and Etch Rate

Tables 8-12 provide (i) comparative stripping solutions and (ii) solutions according to the disclosed and claimed subject matter that were tested using an immersion process to measure Cu etch rate. The thickness of the Cu layer was measured before and after processing for each coupon using RESMAP to estimate the change in thickness and the etch rate.

Different water level of 0%, 15%, 25% and 40% by weight was tested to monitor Cu etch rates of DE solvent and strong bases. The exemplary solutions of the disclosed and claimed subject matter illustrated in Tables 8-12 showed benzoguanamine lowered Cu etch rates significantly regardless of water level using various strong bases. Cu etch rates of formulations containing TEAH and various solvents including DMSO, DE solvent, DB solvent, MMB and TEGME were tested with and without any triazine corrosion inhibitor. The exemplary solutions of the disclosed and claimed subject matter also illustrated that benzoguanamine lowered Cu etch rates significantly in various different solvents and solvent mixtures. As demonstrated, the solutions of the disclosed and claimed subject matter illustrated that use of benzoguanamine unexpectedly lowered Cu etch rates significantly regardless of strong bases.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. A photoresist stripper and etch residue remover solution comprising:
(i) one or more base component comprising one or more of an amine, a quaternary ammonium hydroxide, an inorganic base and combination thereof;
(ii) one or more organic solvents; and
(iii) one or more guanamine compounds of Formula 2: 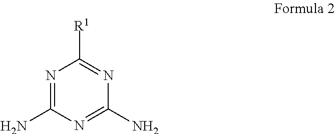
wherein R¹ is selected from a hydrogen atom, an oxygen-containing group, a hydroxyl group, a mercapto group, a nitrogen-containing group, an amine, an amino group substituted with a C₁-C₁₀ alkyl group, a carboxyl group, a phenyl group, a substituted phenyl group, an alkoxy group, a C₁ to C₂₀ linear alkyl group, a C₃ to C₂₀ branched alkyl group, a C₃ to C₁₀ cyclic alkyl group, a C₅ to C₁₂ aryl group, a C₂ to C₁₀ linear alkenyl group, a C₃ to C₁₀ branched alkenyl group, a C₂ to C₁₀ linear alkynyl group, a C₃ to C₁₀ branched alkynyl group, a C₁ to C₂₀ linear alkyl group substituted with a halide and a C₁-C₂₀ alkyl substituted with

[symbol]

2. The photoresist stripper and etch residue remover solution of claim 1, wherein the solution is free of DMSO.

3. (canceled)

4. The photoresist stripper and etch residue remover solution of claim 1, wherein R¹ is selected from hydrogen, an —OH group, a phenyl group, a substituted phenyl group, an amine, a carboxyl group, a C₁-C₆ linear alkyl group and a C₃-C₆ branched chain alky group.

5. (canceled)

6. (canceled)

7. The photoresist stripper and etch residue remover solution of claim 1, wherein R¹ is a phenyl group.

8. The photoresist stripper and etch residue remover solution of claim 1, wherein R¹ is a substituted phenyl group.

9-12. (canceled)

13. The photoresist stripper and etch residue remover solution of claim 1, wherein the (i) one or more base component comprises one or more of DMDPAH, TEAH, KOH, TMAH, ETMAH, choline hydroxide and monocthanolamine.

14-20. (canceled)

21. The photoresist stripper and etch residue remover solution of claim 1, wherein the (ii) one or more organic solvents comprises one or more of DMSO, propylene glycol, diethylene glycol monoethyl ether, diethylene glycol monobutyl ether, triethylene glycol monomethyl ether and 3-methoxy-3-methyl-1-butanol.

22. The photoresist stripper and etch residue remover solution of claim 1 further comprising water as (iv) one or more secondary solvent.

23. The photoresist stripper and etch residue remover solution of claim 1 further comprising water as (iv) one or more secondary solvent and wherein the amount (wt %) of the (ii) one or more organic solvents exceeds the amount (wt %) of the (iv) one or more secondary solvent.

24. The photoresist stripper and etch residue remover solution of claim 1 further comprising one or more of resorcinol, BZT, sorbitol, 8-HQ and copper (II) nitrate as a (v) one or more non-triazine corrosion inhibitor.

25-30. (canceled)

31. The photoresist stripper and etch residue remover solution of claim 1 further comprising BZT and one or more of resorcinol, sorbitol, 8-HQ and copper (II) nitrate as a (v) one or more non-triazine corrosion inhibitor.

32. The photoresist stripper and etch residue remover solution of claim 1 comprising
(i) about 10 wt % to about 15 wt % of TEAH;
(ii) about 46.5 wt % to about 62.5 wt % of one or more of diethylene glycol monoethyl ether, diethylene glycol monobutyl ether, triethylene glycol monomethyl ether and 3-methoxy-3-methyl-1-butanol;
(iii) about 0.25 wt % to about 0.75 wt % benzoguanamine; and
(iv) about 24 wt % to about 40 wt % of water,
wherein the solution is free of DMSO.

33. The photoresist stripper and etch residue remover solution of claim 32, comprising about 13 wt % of TEAH.

34. The photoresist stripper and etch residue remover solution of claim 32, comprising about 0.5 wt % benzoguanamine.

35. The photoresist stripper and etch residue remover solution of claim 32, comprising about 40 wt % of water.

36. The photoresist stripper and etch residue remover solution of claim 32, comprising about 24 wt % of water.

37. The photoresist stripper and etch residue remover solution of claim 32, comprising about 62.5 wt % of diethylene glycol monoethyl ether.

38-42. (canceled)

43. The photoresist stripper and etch residue remover solution of claim 1 comprising
(i) about 1.75 wt % to about 2.0 wt % of KOH;
(ii) about 55 wt % to about 97.5 wt % of diethylene glycol monoethyl ether;
(iii) about 0.25 wt % to about 0.75 wt % benzoguanamine; and
(iv) a balance of water.

44-49. (canceled)

50. The photoresist stripper and etch residue remover solution of claim 1 comprising
(i) about 2.5 wt % to about 3.0 wt % of DMDPAH;
(ii) about 10.5 wt % of propylene glycol and about 45 wt % to about 86.5 wt % of diethylene glycol monoethyl ether;
(iii) about 0.25 wt % to about 0.75 wt % benzoguanamine; and
(iv) a balance of water.

51-62. (canceled)

63. The photoresist stripper and etch residue remover solution of claim 1 comprising
(i) about 2.6 wt % of DMDPAH and about 6 wt % of monoethanolamine;
(ii) about 80 wt % of DMSO and about 10.5 wt % of propylene glycol; and
(iii) about 0.75 wt % to about 1.0 wt % of benzoguanamine.

64. (canceled)

65. (canceled)

66. The photoresist stripper and etch residue remover solution of claim 63, further comprising one or more of resorcinol, 8-HQ, copper nitrate, histidine and sorbitol.

67-72. (canceled)

73. A method for removing a photoresist or etch residue from a substrate comprising the steps of:
(i) contacting the substrate with one or more of the photoresist stripper and etch residue remover solutions of claim 1 for a time sufficient to remove a desired amount of the photoresist or etch residue;
(ii) removing the substrate from the solution;
(iii) rinsing the solution from the substrate with DI water or a solvent; and
(iv) optionally drying the substrate.
